(19) United States
(12) Patent Application Publication
(10) Pub. No.: US 2011/0121738 A1
(43) Pub. Date: May 26, 2011

(54) LIGHT-EMITTING APPARATUS

(75) Inventors: Fujio Kawano, Kawasaki-shi (JP); Masami Iseki, Mobara-shi (JP); Kohei Nagayama, Chiba-shi (JP); Nobuhiko Sato, Mobara-shi (JP); Toshihiko Mimura, Tokyo (JP); Hiroyuki Maru, Kawasaki-shi (JP); Yutaka Inaba, Hino-shi (JP)

(73) Assignee: CANON KABUSHIKI KAISHA, Tokyo (JP)

(21) Appl. No.: 13/000,001

(22) PCT Filed: Jun. 19, 2009
(86) PCT No.: PCT/JP2009/061669

§ 371 Date: Dec. 17, 2010

(30) Foreign Application Priority Data
Jun. 20, 2008 (JP) 2008-162317
Jun. 30, 2008 (JP) 2008-170687
Mar. 17, 2009 (JP) 2009-064676

(51) Int. Cl. H05B 37/00

(52) U.S. Cl. 315/130

(57) ABSTRACT

A light-emitting apparatus includes a plurality of light-emitting devices which are connected in series and formed by alternately disposing electrodes and organic layers including a light-emitting material, wherein the electrodes include one electrode and another electrode disposed at an anode end and a cathode end of the light-emitting devices, respectively, and an intermediate electrode disposed between two of the organic layers which serves as a cathode of the light-emitting device disposed on a side of the anode end and as an anode of the light-emitting device disposed on a side of the cathode end; the intermediate electrode is connected to a drive circuit having two current output terminals connected in common; the drive circuit receives data signals concerning two of the plurality of light-emitting devices for which the intermediate electrode serves as the anode and the cathode, respectively; and the drive circuit outputs currents which are different in direction from each other from the two current output terminals in response to the received data signals.

### TECHNICAL FIELD

The present invention relates to a light-emitting apparatus, and more particularly to a light-emitting apparatus in which organic electroluminescence (hereinafter, referred to as “EL”) devices each emitting light of red (R), green (G), and blue (B) respectively are stacked, and the respective organic EL devices are applied with a desired constant current.

### BACKGROUND ART

An example of a display apparatus using an organic EL device includes a stacked type organic EL display apparatus in which organic EL devices are stacked and respective layers of the organic EL devices are driven independently of one another to emit light.

International Publication No. WO2004/051614 discloses a stacked type light-emitting device which includes light-emitting layers of R, G, B, which are respectively disposed in each gap between a bottom electrode at a reference potential and three layers of electrodes provided above the bottom electrode. The three layers of electrodes above the bottom electrode are each supplied with a voltage via a switching transistor. A drive circuit for applying a voltage to each of the three layers is formed of fixed voltage generation circuits which are connected in series.

Japanese Patent Application Laid-Open No. 2007-012359 discloses a stacked type light-emitting device which includes three organic EL devices of R, G, and B, each including an anode, a cathode, and a light emitting layer, and the three organic EL devices are stacked between laminated electrodes with an insulating layer sandwiched therebetween. Each of the respective organic EL devices is connected to a drive circuit for outputtting a current corresponding to each luminance, and emits light of the luminance. The respective layers are electrically separated through the insulating layer, and the drive circuit supplies the current to only one of the light-emitting devices. Accordingly, the drive circuit is merely required to generate the current in one direction as in the case of an ordinary non-stacked type organic EL device.

Japanese Patent Application Laid-Open No. 2005-174639 discloses an organic EL device, in which two layers of organic EL devices of different colors are stacked, an upper electrode and a lower electrode are short-circuited and grounded, and an electrode in the middle is alternately applied with a positive voltage and a negative voltage, to thereby cause the two layers of the organic EL devices to alternately emit light. The positive voltage and the negative voltage are each adjusted in amplitude, to thereby change the luminance ratio between the two layers.

According to a method of controlling light emission of the organic EL devices through application of a voltage thereto, there is a drawback in that a current flowing therethrough differs in value even under the same voltage applied, when there is a variation or a temporal change in the volt-ampere characteristic of the organic EL devices, resulting in that the luminance may not be controlled with accuracy.

On the other hand, according to a current driving method of controlling a current flowing through the organic EL devices, a variation or a temporal change in the volt-ampere characteristic of the organic EL devices do not affect the luminance as long as the relation between the current and the luminance is kept constant.

According to a stacked type organic EL device in which an electrode provided between two of the organic EL devices is shared by both of the organic EL devices, the device may be caused to emit light through application of a voltage signal corresponding to the luminance across the respective electrodes. However, in controlling the luminance by providing a current signal, a difference of currents flowing through the upper and lower organic EL devices flows through an intermediate electrode sandwiched by the organic EL devices, which makes it difficult to control the current. When the intermediate electrode is kept at a fixed voltage, while each of the upper and lower organic EL devices is supplied with a controlled current through another one of the electrodes, currents flowing through the respective organic EL devices may be directly controlled. However, this method may not be applied to a stacked type organic EL devices having three or more layers. In the case of the stacked type organic EL devices having three or more layers, there is no other choice but to provide an electrode between the upper and lower organic EL devices as two-layered electrodes having an insulating layer sandwiched therebetween, but not as a single-layer electrode to be shared by the upper and lower organic EL devices, to thereby make the upper and lower organic EL devices electrically independent of each other.

### DISCLOSURE OF THE INVENTION

An object of the present invention is to provide a drive circuit and a driving method which are suitable for current drive of an active matrix type display apparatus which drives organic EL devices having a stacked structure using a transistor.

The present invention relates to a light-emitting apparatus including a plurality of light-emitting devices which are connected in series and formed by alternately disposing electrodes and organic layers including a light-emitting material, wherein

the electrodes include one electrode and another electrode disposed at an anode end and a cathode end of the light-emitting devices, respectively, and an intermediate electrode disposed between two of the organic layers which serves as a cathode of the light-emitting device disposed on a side of the anode end and as an anode of the light-emitting device disposed on a side of the cathode end;

the intermediate electrode is connected to a drive circuit having two current output terminals connected in common;

the drive circuit receives data signals concerning two of the plurality of light-emitting devices for which the intermediate electrode serves as the anode and the cathode, respectively; and

the drive circuit outputs currents which are different in direction from each other from the two current output terminals in response to the received data signals.

According to the present invention, there is no need to sandwich an insulating layer such as an oxide film between the stacked organic EL devices, which simplifies a device structure and reduces a manufacturing cost as well. In addition, light-emitting luminance is analog-controlled by a current, and hence accuracy of halftone is high.

Further features of the present invention will become apparent from the following description of exemplary embodiments with reference to the attached drawings.

### BRIEF DESCRIPTION OF THE DRAWINGS

FIG. 1 is a schematic view illustrating a pixel arrangement and provision directions of signal lines of a light-emitting apparatus according to the present invention.

FIG. 2 is a sectional view of a stacked type organic EL device for use in the light-emitting apparatus according to the present invention.

FIG. 3 is a circuit diagram of a stacked type organic EL device and current sources according to the first embodiment of the present invention.

FIGS. 4A, 4B and 4C are each specific circuit diagrams of the current sources according to the first embodiment of the present invention.

FIG. 5 illustrates a modification example of the current sources according to the first embodiment of the present invention.

FIG. 6 is a circuit diagram of a stacked type organic EL device and current sources according to a second embodiment of the present invention.

FIGS. 7A, 7B and 7C are each specific circuit diagrams of the current sources according to the second embodiment of the present invention.

FIG. 8 is a block diagram of a signal generating circuit according to the second embodiment of the present invention.

FIG. 9 is a diagram illustrating a cross-section of a stacked type organic EL device according to a third embodiment of the present invention and connection of circuits therewith.

FIG. 10 is a block diagram of the circuits according to the third embodiment of the present invention.

FIG. 11 is a specific diagram of the circuits according to the third embodiment of the present invention.

FIG. 12 is a timing chart illustrating operations of the circuits according to the third embodiment of the present invention.

FIG. 13 is a diagram illustrating a cross-section of a stacked type organic EL device according to a fourth embodiment of the present invention and connection of circuits therewith.

FIG. 14 is a specific diagram of the circuits according to the fourth embodiment of the present invention.

FIG. 15 is a timing chart illustrating operations of the circuits according to the fourth embodiment of the present invention.

FIG. 16 is a specific diagram of circuits according to a fifth embodiment of the present invention.

FIG. 17 is a timing chart illustrating operations of the circuits according to the fifth embodiment of the present invention.

FIG. 18 is a diagram for describing scanning of a matrix display apparatus to which the present invention is applied.

FIG. 19 illustrates a first modification example of the circuits according to the fifth embodiment of the present invention.

FIG. 20 is a timing chart illustrating operations of the circuits of the first modification example.

FIG. 21 is a partially enlarged diagram of the timing chart of FIG. 20.

FIG. 22 illustrates a second modification example of the circuits according to the fifth embodiment of the present invention.

FIG. 23 is a timing chart illustrating operations of the circuits of the second modification example.

FIG. 24 is a partially enlarged diagram of the timing chart of FIG. 23.

FIG. 25 illustrates a third modification example the circuits according to the fifth embodiment of the present invention.

FIG. 26 is a timing chart illustrating operations of the circuits of the third modification example.

### BEST MODE FOR CARRYING OUT THE INVENTION

Preferred embodiments of the present invention will now be described in detail in accordance with the accompanying drawings.

First, a matrix display apparatus to which a light-emitting apparatus according to the present invention is mainly applied is described.

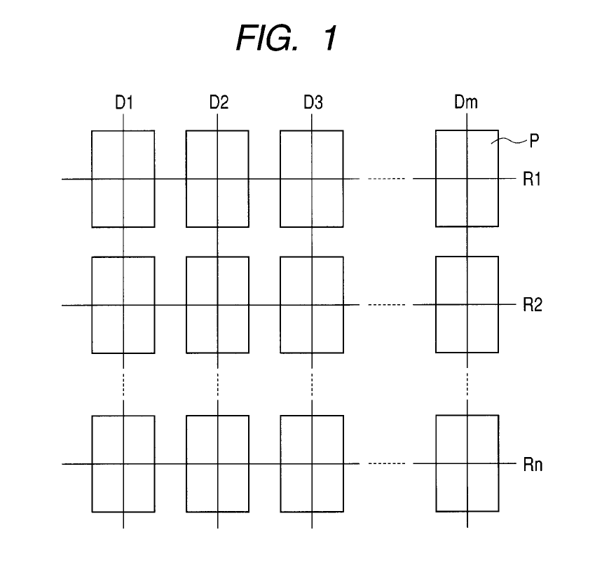

FIG. 1 is a diagram illustrating a pixel arrangement of the matrix display apparatus and provision form of scanning lines and data lines.

The pixels P are disposed in a row direction and in a column direction to form a matrix of n rows and m columns. There are disposed scanning lines R1, R2, . . . , and Rn (n lines in total, and hereinafter, referred to as R representatively) which connect the pixels in the row direction, and data lines D1, D2, . . . , and Dm (m lines in total, and hereinafter, referred to as D representatively) which connect the pixels in the column direction. The scanning lines R are sequentially applied with selection signals to select pixels in units of a row. The data lines D in the column direction are applied with a display signal which fluctuates in time, and the pixel P of the selected row is supplied with the display signals on that occasion.

Programming refers to an operation in which the selection signals are sequentially applied to the scanning lines R, and video signals are supplied to the respective pixels P of the selected row from the data line D, whereby the video signals are held by a voltage holding mechanism such as a capacitor provided in the pixel. A period in which the selection signals are applied to the scanning lines R of each row is a programming period. This period is shifted in time by one programming period for each row.

Each row moves into a light-emitting period when the programming period is finished. A circuit provided in each of the pixels generates a current corresponding to the video signal held in the holding capacitor and supplies the generated current to a light-emitting device. The light-emitting device emits light at a luminance corresponding to the generated current.

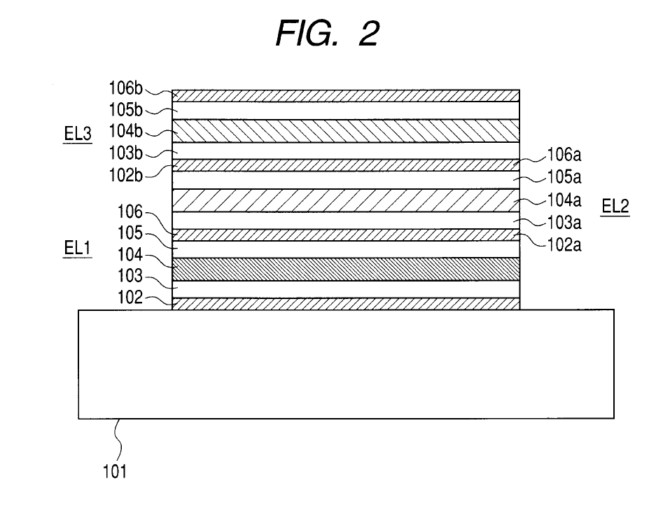

FIG. 2 illustrates an example of the light-emitting device included in the pixel P of FIG. 1, which is a stacked type light-emitting device in which three layers of organic EL devices are stacked on a glass substrate 101. The organic EL device is described as an example hereinbelow. However, the present invention is not limited to the organic EL device and is widely applicable to any light-emitting device which emits light in response to a current.

One organic EL device has a structure in which organic layers including a light-emitting layer (hereinafter, sometimes simply referred to as “emission layer”) are sandwiched between an anode and a cathode. In an organic EL device EL1 stacked at the bottom of the organic EL device, an anode 102, a hole transport layer 103, a light-emitting layer 104, and an electron transport layer 105 are stacked in the stated order, and a cathode 106 is disposed thereon.

The cathode 106 also serves as an anode 102a of a second organic EL device EL2 stacked on the organic EL device EL1. The second organic EL device EL2 has the same structure, in which organic layers of a hole transport layer 103a, a light-emitting layer 104a, and an electron transport layer 105a are stacked, and a cathode 106a covers those organic layers.

Furthermore, the cathode 106a also serves as an anode 102b of a third organic EL device EL3. A hole transport layer 103b, a light-emitting layer 104b, and an electron transport layer 105b are stacked, and a cathode 106b which is disposed as the outermost layer to complete the stacked layers.

The light-emitting layer 104, 104a, and 104b contain light-emitting materials different from each other, and emit light in different colors. Hereinafter, the colors are red (R), green (G), and blue (B) in order from the bottom for convenience, but the colors may be in any order.

One organic EL device is formed of one organic layer and electrodes formed thereabove and therebelow. The stacked structure enables the formation of the light-emitting devices connected in series. In the light-emitting devices connected in series, an anode of the organic EL device formed in a position closest to the substrate forms an anode end, while a cathode of the organic EL device formed at the top of the stacked structure forms a cathode end. Electrodes other than the above-mentioned electrodes are sandwiched by two organic layers stacked thereabove and therebelow. Those intermediate electrodes each serve as a cathode of the organic layer formed on the anode end side and also as an anode of the organic layer formed on the cathode end side.

In a structure of one organic EL device, an electron injection layer, a hole injection layer, and other functional layers may be included in addition to the above-mentioned layers. There is also proposed a structure in which the light-emitting layer 104 serves also as the hole transport layer 103, as the electron transport layer 105, or as both of the above-mentioned layers.

When a current is caused to flow through the organic EL device from the electrode closest to the hole injection layer, that is the anode, to the electrode which is close to the electron injection layer, that is the cathode, electrons and holes, which are injected from the respective electrodes, are combined in the light-emitting layer 104, whereby light is emitted. A light-emitting luminance increases in proportion to a magnitude of the current. The organic EL device may be referred to as a current-controlled type light-emitting device in some cases. Only a small amount of current flows and light is not emitted when a voltage is applied in a reverse direction. In this manner, the organic EL device has rectifying characteristics in which a direction of a current for emitting light is fixed, and may be regarded as a diode in terms of a circuit.

All of the organic EL devices EL1 to EL3 emit light when a current flows in a direction from a lower position close to the substrate to an upper position farther from the substrate. The structure in which the order of the respective layers of FIG. 2 is vertically reversed is also conceivable, and in such a case, light is emitted when the current flows from top to bottom in the all organic EL devices EL1 to EL3. The present invention is applicable to such a stacked type light-emitting device as the one described above in which a direction of the current with respect to the substrate is the same among all layers.

### First Embodiment

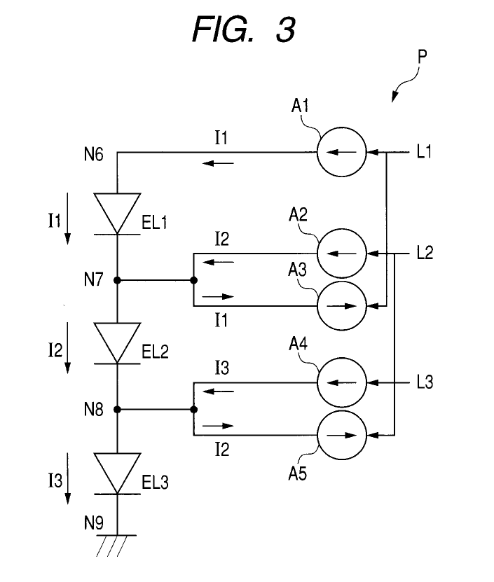

FIG. 3 is a diagram illustrating a light-emitting apparatus according to a first embodiment of the present invention.

A pixel P, which is a unit of the light-emitting apparatus, includes organic EL devices EL1 to EL3 which are stacked in three layers and current sources A1 to A5 which form a drive circuit therefor. The respective organic EL devices have diode characteristics, and emit light in response to a forward current. The organic EL devices EL1 to EL3 of FIG. 3 correspond to the organic EL devices EL1 to EL3 illustrated in FIG. 2, respectively. FIG. 3 is drawn in the vertical direction opposite to FIG. 2.

As described above, the organic EL devices EL1, EL2, and EL3 of three colors R, G, and B are stacked so that the currents for light-emitting have the same direction (direction farther from the substrate). Of electrodes at both ends of the pixel P, an electrode N9 at one end thereof (cathode 106b at one end thereof illustrated in FIG. 2) is connected to a fixed voltage source (ground potential), and has a fixed potential. A unidirectional current source A1 is connected to an electrode N6 at another end of the pixel P (anode 102 at another end thereof illustrated in FIG. 2). Current sources A2 and A3 are connected to an intermediate electrode N7 (cathode 106 as well as anode 102a of FIG. 2) vertically sandwiched between the organic layers, while current sources A4 and A5 are connected to another intermediate electrode N8 (cathode 106a as well as anode 102b of FIG. 2).

The current sources A1 to A5 are each formed by a current source circuit in which an output current value is determined according to a voltage signal input thereto, and a specific current configuration of the current sources A1 to A5 is described below. The current flows through the current sources A1, A2, and A4 in a direction in which the current flows from an output terminal thereof to an outside thereof, while the current flows through the current sources A3 and A5 in a direction in which the current flows from the outside thereof to the output terminal thereof. The current source circuit is generally any one of a current source in which a current flows from a fixed voltage source toward the output terminal thereof and a current sink to which the current is drawn from the output terminal thereof toward the fixed voltage source, and is a unidirectional current source. A bidirectional current source which serves as a source and a sink may be regarded as two unidirectional current sources which are connected in parallel.

An output impedance of the current source is sufficiently high, and a voltage at the output terminal thereof may be appropriately changed according to a load. However, an upper limit and a lower limit of the voltage at the output terminal are determined by a source voltage of the current source itself (in a case where an output current flows out from the output terminal, a voltage higher than a load, while in a case where the output current flows into the output terminal, a voltage lower than the load).

When the current source is simply mentioned herein below, the unidirectional current source is referred to. A current source in which two unidirectional current sources, which output currents of opposite directions, are connected in parallel is referred to as a bidirectional current source. The current sources A2 and A3 in combination with each other serve as one bidirectional current source. The same holds true for the current sources A4 and A5.

In the pixel P, of a pair of outer electrodes positioned in the uppermost and lowermost parts of the stacked layer, the outer electrode N6 in the upper part (lowermost part in FIG. 2) is connected to the current source A1 as a drive circuit, and the outermost-layer electrode N9 in the lower part is connected to the fixed voltage source (ground potential). The current sources A2 and A3 are connected as the drive circuit to the intermediate electrode N7, and the current sources A4 and A5 are connected as the drive circuit to the intermediate electrode N8.

A luminance signal L1 of the first organic EL device EL1 is input to the current source A1 connected to the outer electrode N6 positioned in the upper part of the pixel P (hereinafter, a vertical direction is a direction of FIG. 3), and an output current I1 according to the luminance signal L1 is output therefrom. The output direction of the current source A1 is a direction in which the forward current of the first organic EL device EL1 flows, that is, a direction in which a current accompanying light-emitting flows.

The current source A2 having the direction, in which the current flows into the intermediate electrode N7, and the current source A3 having the direction, in which the current is drawn from the intermediate electrode N7, are connected in parallel to the intermediate electrode N7 positioned below the outer electrode N6. A signal L2, which provides a luminance of the second organic EL device EL2, is input to the current source A2, and an output current I2 is output therefrom. A signal L1, which provides a luminance of the first organic EL device EL1, is input to the current source A3, and the output current I1 is output therefrom. As a result, a current of a difference between the current sources A2 and A3 flows into the intermediate electrode N7 (a differential current flows out of the intermediate electrode N7 in a case where I1 is larger than I2, but it is assumed herein that a negative current flows thereinto, and thus one of the descriptions above is used hereinbelow), and thus, the output current I2 flows through the second organic EL device.

When the current sources A2 and A3 are regarded as one drive circuit for the intermediate electrode N7, this drive circuit has two current output terminals (output terminal of A2 and output terminal of A3) for outputting currents of opposite directions, and those current output terminals are connected in common to supply the current to the intermediate, electrode N7.

The current source A4 having a direction, in which the current flows into the intermediate electrode N8, and the current source A5 having a direction, in which the current is drawn from the intermediate electrode N8, are connected in parallel to the second intermediate electrode N8 positioned below the intermediate electrode N7. A luminance signal L3 and a luminance signal L2 are input to the current source A4 and the current source A5, respectively, and a current I3 and a current I2 are output therefrom, respectively. As a result, the third organic EL device is supplied with the current I3.

When the current sources A4 and A5 are regarded as one drive circuit, this drive circuit has two current output terminals for outputting currents of opposite directions. Those output terminals are connected in common, and a current is supplied to the intermediate electrode N8.

As can be seen from the above, the drive circuits connected to the intermediate electrodes N7 and N8 are circuits in which the current sources in opposite direction to each other are connected to the respective intermediate electrodes with an output being in common.

Next, as to an input signal and an output of the drive circuit, the luminance signals L1 and L2 of the two organic EL devices EL1 and EL2 which are formed at both sides of the intermediate electrode N7 with the intermediate electrode N7 being as a common electrode are input to the current sources A2 and A3, respectively. Of the two organic EL devices EL1 and EL2, the luminance signal L2 of the organic EL device EL2 for which the intermediate electrode N7 serves as the anode is input to the current source A2 serving as a source from which the current flows, and the output current I2 which flows in a direction in which the current flows toward the intermediate electrode N7 is generated. The luminance signal L1 of the organic EL device EL1 for which the intermediate electrode N7 serves as the cathode is input to the current source A3 serving as the sink into which the current flows, and the output current I1 is generated in a direction in which the current is drawn from the intermediate electrode N7. As the bidirectional current source, a differential current therebetween is output. The same holds true for the intermediate electrode N8.

When the outer electrode N6, and a group of current sources connected to the intermediate electrodes N7 and N8 are taken as a whole, current sources which are equal in absolute value to each other and different in direction from each other are included therein.

The current sources A1 and A2 which have the same output current I1 and different directions from each other are connected to a pair of electrodes N6 and N7 which form one organic EL device, for example, the organic EL device EL1, respectively. The current I1 flows only through the organic EL device EL1 but does not flow through the other organic EL devices EL2 and EL3. In addition, the current sources A3 and A4 to which the luminance signals L1 and L3 of the other organic EL devices EL1 and EL3 are input are connected to the intermediate electrodes N7 and N8 of the organic EL device EL2, but the current thereof does not flow through the organic EL device EL2. In this manner, the currents which flow through the organic EL devices of the respective layers are accurately controlled.

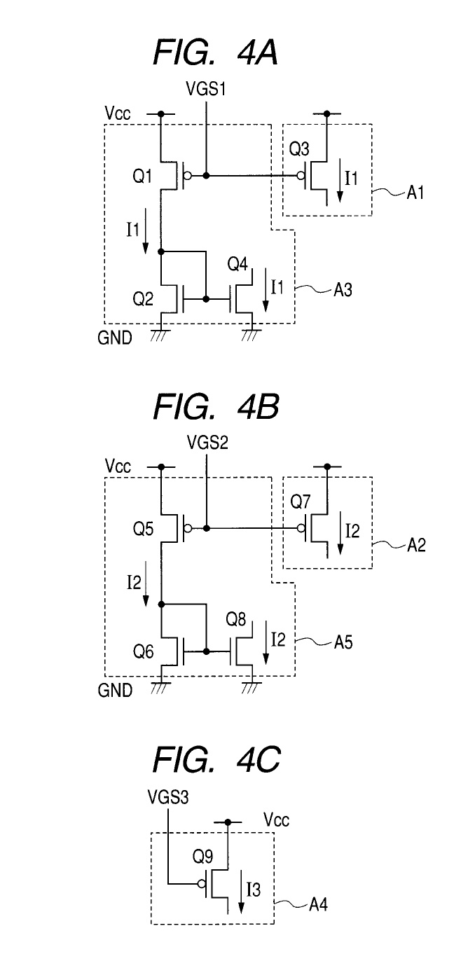

FIGS. 4A to 4C illustrate specific examples of the circuits of the current sources A1 to A5 of FIG. 3. Reference symbols A1 to A5 of FIGS. 4A to 4C correspond to the current sources A1 to A5 of FIG. 3. The current sources A1 to A5 are formed by a PMOS transistor in which a voltage between a gate and a source thereof is controlled or by an NMOS transistor.

FIG. 4A illustrates a current source circuit for outputting the same current I1 in an opposite direction, which is a circuit corresponding to the current sources A1 and A3 of FIG. 3. The current source circuit of FIG. 4A is formed of PMOS transistors Q1 and Q3 in which gates thereof are connected in common, and NMOS transistors Q2 and Q4 in which gates thereof are connected in common. Two transistors of each pair are selected such that characteristics thereof are substantially the same.

A gate and a drain of the NMOS transistor Q2 are short-circuited, and a gate potential thereof is determined by a current which flows through the NMOS transistor Q2.

Reference symbol VGS1 denotes an input voltage signal generated from the luminance signal L1 of the first organic EL device EL1 by a signal processing circuit (not shown). The digital luminance signal L1 input from a circuit outside the light-emitting apparatus to the signal processing circuit, is converted into a digital signal corresponding to a current to be caused to flow through the organic EL device via a gamma-correction circuit (not shown) included in the signal processing circuit, and further converted into an analog voltage signal VGS1 by a voltage signal generating circuit (not shown) which is also included in the signal processing circuit.

When the voltage signal VGS1 is applied as a voltage between a gate and a source of the PMOS transistor Q1, a current determined by the following equation is generated in the PMOS transistor Q1 and the NMOS transistor Q2 which are connected in series between a power source Vcc and GND.

$$I 1 = β 1 ( VGS 1 - Vth 1 ) ( Vcc - Vd ) = \frac{1}{2} β 2 {( Vd - Vth 2 )}^{2}$$

Here, Vd represents a drain potential of the PMOS transistor Q1, which is determined by solving the second equation of the equation above. β1 and β2 represent current multiplication factors of the transistors Q1 and Q2, and Vth1 and Vth2 represent threshold voltages. The voltage signal generating circuit determines the voltage signal VGS1 so that the output current I1 is coincide with current data provided from the luminance signal L1.

The PMOS transistor Q3 and the NMOS transistor Q4 have the gates connected in common with the PMOS transistor Q1 and the NMOS transistor Q2, respectively, and thus form a current mirror circuit with respect to a current path formed by the PMOS transistor Q1 and the NMOS transistor Q2. In other words, when a load is connected to the drain of the PMOS transistor Q3 or the drain of the NMOS transistor Q4, the currents I1 having the same amount of the currents flowing through the PMOS transistor Q1 and the NMOS transistor Q2 flow through the load. Those currents have a direction in which the current flows from the PMOS transistor Q3 and a direction in which the current flows into the NMOS transistor Q4, respectively, and function as the current sources A1 and A3 of FIG. 2, respectively.

FIG. 4B illustrates a specific example of a circuit formed by the current sources A2 and A5 of FIG. 3. This circuit operates in completely the same manner as the circuit of FIG. 4A. A voltage signal VGS2 to be input to a gate of a PMOS transistor Q5 is a signal for providing a luminance of the second organic EL device EL2. A current I2 in the opposite direction is generated by a PMOS transistor Q7 and an NMOS transistor Q6.

FIG. 4C illustrates a circuit formed of the current source 4 of FIG. 3. An input voltage signal VGS2 corresponding to the luminance of the third organic EL device EL3 is input to a gate of a PMOS transistor Q9, and thus a current I3 corresponding to the luminance of the organic EL device EL3 flows from the PMOS transistor Q9.

The current sources A1 to A5 of FIG. 3 are formed by the circuits of FIGS. 4A to 4C. An output of the current source A1 and an output of the current source A3 are respectively generated from the current which flows through one path (PMOS transistor Q1 and NMOS transistor Q2) by the two current mirror circuits, and thus are currents equal in absolute value to each other. The same holds true for the current sources A2 and A5. Accordingly, predetermined currents, that is, the currents I1, 12, and 13 flow through the organic EL devices EL1, EL2, and EL3, respectively.

In the example of the circuit illustrated in FIG. 3, a luminance voltage signal VGS is input between a gate and a source of a PMOS transistor to obtain a desired current. Even when a value of a voltage signal VGS set to a level of an NMOS transistor is input between a gate and a source of an NMOS transistor, a desired current may be similarly obtained.

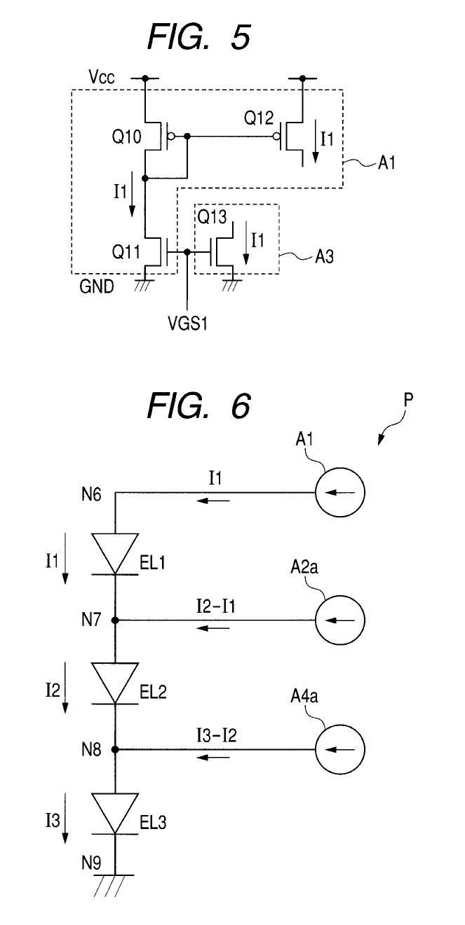

FIG. 5 illustrates a modification example of the circuit of FIG. 4A, which is an example in which the voltage signal VGS is input to the NMOS transistor. Reference symbols Q1 to Q4 of FIG. 4A correspond to reference symbols Q10 to Q13 of FIG. 5, respectively. FIG. 5 is different from FIG. 4A in that a gate and a drain of a PMOS transistor Q10 are short-circuited, and that the voltage signal VGS1 is input between a gate and a source of an NMOS transistor Q11.

Currents which have different directions depending on a magnitude of the currents flowing through the organic EL devices thereabove and therebelow flow through the intermediate electrode, and hence luminances of the respective organic EL devices cannot be controlled only by connecting the single current source which outputs only a current in one direction to the intermediate electrode. A total amount of the currents flows through the intermediate electrode when directions of the forward currents of the organic EL devices thereabove and therebelow are not the same, and hence luminance cannot be controlled by the bidirectional current source.

The present invention is configured so that, in the organic EL devices stacked so as to have the same current direction, two current sources are connected to an intermediate electrode, and output currents of the respective current sources are controlled in response to the luminance signals of the organic EL devices above and below the intermediate electrode. Accordingly, there is no need to provide an insulating layer between the organic EL devices to separate the organic EL devices electrically from each other, which simplifies the electrode structure. Moreover, when a current source capable of continuously varying a current is used, halftone luminance may be easily obtained.

In a case where the circuits of FIGS. 4A to 4C and FIG. 5 are used in the respective pixels P of the active matrix display apparatus illustrated in FIG. 1, capacitors are provided in the respective circuits so that voltage signals VGS1 to VGS3 are held by the capacitors. The voltage signals VGS1 to VGS3 are transmitted from an external circuit via the data line D, and controlled by the scanning line R, thereby being taken by the capacitors (not shown in FIG. 1) of the respective pixels P. The circuit including the capacitor is exemplified and described in detail in the third embodiment and embodiments thereafter.

### Second Embodiment

FIG. 6 is a diagram illustrating the stacked type organic EL devices and a drive circuit therefor according to a second embodiment of the present invention. The stacked structure of the organic EL device is the same as that of the first embodiment, but the second embodiment is different from the first embodiment in that current sources A2a and A4a connected to the intermediate electrodes N7 and N8, respectively, are current sources which generate a differential current.

The differential current source A2a connected to the intermediate electrode N7 outputs a difference between the current I1 of the organic EL device EL1 and the current I2 of the organic EL device EL2 with a direction in which a current flows being positive. The differential current source A2a generates a positive current which flows into the intermediate electrode N7 when the current I2 is larger than the current I1, and generates a negative current which flows from the intermediate electrode N7 when the current I2 is smaller than the current I1. Any cases are possible, and therefore the differential current source A2a is a bidirectional current source capable of generating a current in any direction.

The bidirectional current source A4a, which is similar to the differential current source A2a, is connected to the intermediate electrode N8.

In order to generate a differential current, a voltage signal corresponding to a differential current (I2-I1) is input to the differential current source A2a. The voltage signal is obtained from the respective luminance signals of the organic EL devices EL1 and EL2. A voltage signal corresponding to a differential current (I3−I2) is input to the differential current source A4a. The voltage signal is obtained from the respective luminance signals of the organic EL devices EL2 and EL3.

The generation of the differential current keeps electrical power consumption smaller in this embodiment compared with the first embodiment. In the first embodiment, a current of the same amount of the current which flows through the organic EL device flows through the current source connected to the intermediate electrode. In this embodiment, even when a large current flows through the organic EL device, a current obtained from a difference merely flows through the current source, whereby electrical power consumption can be reduced.

Next, the current source circuits A1, A2a, and A4a of FIG. 6 are described in detail by way of a specific example.

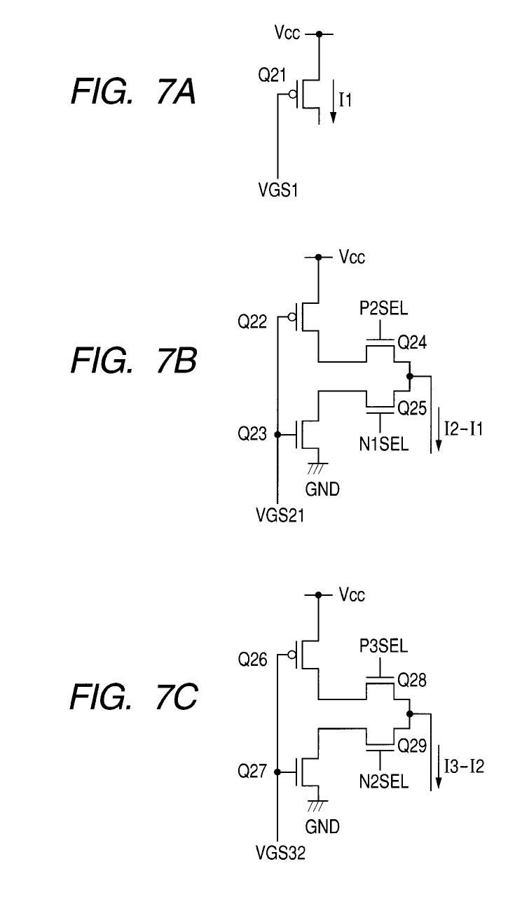

FIGS. 7A to 7C illustrate examples of the circuits of the current sources A1, A2a, and A4a of FIG. 6, respectively.

The current source A1 is formed of a circuit of FIG. 7A, and generates the current I1 based on a luminance signal VGS1. The current source A2a is formed of the circuit of FIG. 7B, and generates the differential current (I2−I1) based on a luminance signal VGS21. Furthermore, the current source A4a is formed of the circuit of FIG. 7C, and generates the differential current (I3−I2) based on a luminance signal VGS32.

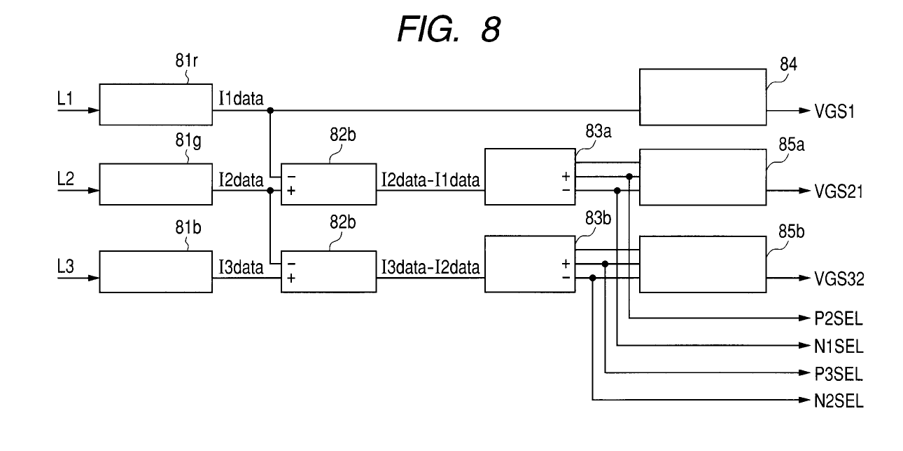

FIG. 8 is a block diagram illustrating a circuit for generating the luminance signals VGS1, VGS21, and VGS31 input to the circuits of FIGS. 7A to 7C, respectively. Reference symbols L1, L2, and L3 denote a luminance signal of the red (R) organic EL device EL1, a luminance signal of the green (G) organic EL device EL2, and a luminance signal of the blue (B) organic EL device EL, respectively.

The luminance signals L1 to L3 in respective colors are input to a current data converting circuits 81r, 81g, and 81b, respectively, and are converted into digital current data I1data, I2data, and I3data, respectively. The current data converting circuit 81 is a converting circuit involving gamma correction, and calculates current data corresponding to the respective R, G, and B organic EL devices based on the luminance signals, and outputs the calculated current data.

The red current data I1data and the green current data I2data are input to a negative input terminal and a positive input terminal of a subtraction circuit 82a, respectively. The subtraction circuit 82a calculates a difference between positive input data and negative input data. The subtraction circuit 82a outputs digital data of a difference (I2data−I1data). In the same manner, the green current data I2data and blue current data I3data are input to a negative input terminal and a positive input terminal of a subtraction circuit 82b, respectively, and the subtraction circuit 82b outputs digital data of a difference (I3data−I2data).

The differential current data is input to absolute value converting circuits 83a and 83b next to the subtraction circuits 82a and 82b. The absolute value converting circuits 83a and 83b determine codes of input digital data, and output code data P2SEL and N1SEL, and code data P3SEL and N2SEL, respectively.

That is, when I2data>I1data, a positive (+) terminal output P2SEL and a negative (−) terminal output N1SEL of the absolute value converting circuit 83a are “1” and “0”, respectively. Conversely, when I2data<I1data, the positive (+) terminal output P2SEL and the negative (−) terminal output N1SEL are “0” and “1”, respectively. At the same time, an absolute value of the input data is output.

In the same manner, the absolute value converting circuit 83b also outputs code data P3SEL and N2SEL and absolute value data according to a magnitude of the current data I3data and I2data.

The absolute value data and the code data of the current are input to circuits 85a and 85b which generate a voltage signal, and the voltage signal generation circuits 85a and 85b convert the absolute value data of the current into the analog voltage signals VGS21 and VGS32, and then output the analog voltage signals VGS21 and VGS32.

The voltage signal generation circuit 85a also refers to the code data, and when the code data P2SEL is “1” (code data N1SEL is “0”), the output voltage is set to the analog voltage signal level so as to be a gate potential of a PMOS transistor, and then is output. In this case, the voltage signal VGS21 is a potential at a level lower than the power source voltage Vcc of the current source circuit by a threshold or more. The potential becomes smaller as the absolute value output of the differential current increases.

Conversely, when the code data P2SEL is “0” (code data N1SEL is “1”), the output voltage is set to the analog voltage signal level so as to be a voltage between a gate and a source of an NMOS transistor. The voltage signal VGS21 has a potential at a level higher than a ground voltage GND of the power source circuit by the threshold or more. The potential becomes higher as the absolute value output of the differential current increases.

An operation of the voltage signal generation circuit 85b is completely the same as that of the voltage signal generation circuit 85a.

The differential current sources A2a and A4a need to be configured so as to output a potential difference of the organic EL device positioned therebelow and the organic EL device positioned thereabove. The luminance signal and the current value corresponding thereto generally have a non-linear relationship, and thus, if a difference of the luminance signal itself is taken, the output current obtained therefrom is not accurate. In the circuit of FIG. 8, a luminance signal is temporarily converted into a current value to calculate a difference, and the difference is converted into a voltage signal to be output. Accordingly, an accurate differential current output can be obtained.

Apart from this, the red current data I1data generated by the current data converting circuit 81r is input to a current 84 which generates a voltage signal. The voltage signal generation circuit 84 outputs the voltage signal VGS1 at a level of a voltage between a gate and a source of a PMOS transistor irrespective of the code of the input current data I1data.

The voltage signals VGS1, VGS21, and VGS32 output from the voltage signal generation circuits 84, 85a, and 85b are input to the current source circuit of FIG. 6, respectively, together with the code data P2SEL, N1SEL, P3SEl, and N2SEL, which are output by the absolute value converting circuits 83a and 83b.

When the voltage signal VGS1 generated from the red luminance signal L1 is input to the gate of the PMOS transistor Q21 of FIG. 7A, the current I1 is generated to be caused to flow through the red organic EL device EL1, whereby light is emitted with a luminance of L1.

The voltage signal VGS21 generated from the red luminance signal L1 and the green luminance signal L2 is input in common to the gate of the PMOS transistor Q22 and the gate of the NMOS transistor Q23 of FIG. 7B. The voltage signal VGS21 controls the current which flows through any one of the PMOS transistor Q22 and the NMOS transistor Q23 according to a positive value or a negative value of the differential current (I2data−I1data).

When the differential current (I2data−I1data) is positive, that is, when the current which flows through the green organic EL device EL2 is larger than the current which flows through the red organic EL device EL1, the voltage signal VGS21 is at the PMOS control level. Accordingly, the PMOS transistor Q22 generates a current (I2−I1) in a direction in which the current flows toward the output terminal.

As to the code output, the positive (+) output P2SEL is “1” and the negative (−) output N1SEL is “0”, whereby the gate Q24 is conducted and the gate Q25 is closed. For this reason, the current of the NMOS transistor Q23 is interrupted, and the current (I2−I1) from the PMOS transistor Q22 is output as the output current. The current has a direction in which the current flows into the intermediate electrode N7, and thus combined with the current I1 flowing through the organic EL device EL1 in the intermediate electrode N7. Accordingly, the current I2 is supplied to the green organic EL device EL2.

When the differential current (I2data−I1data) is negative, that is, when a current of the red organic EL device is larger than a current of the green organic EL device, the current (I1−I2) which flows into the NMOS transistor Q23 is output as an output current. The output current flows in a direction in which the current is drawn from the intermediate electrode N7. Accordingly, the output current is subtracted from the current I1 which has flowed through the organic EL device EL1, whereas the remaining current I2 flows through the green organic EL device EL2.

In any case, the current I2 corresponding to the predetermined luminance L2 flows through the green organic EL device EL2.

An operation of the current source A4a illustrated in FIG. 7C is similar to that of the circuit illustrated in FIG. 7B, and thus a predetermined current flows through the blue organic EL device EL3 irrespective of a magnitude of the current flowing through the green organic EL device EL2.

The current source circuits A2a and A4a may output a current bidirectionally, and thus the current source circuits of FIGS. 7B and 7C include output transistors of two polarities, that is, a PMOS transistor and an NMOS transistor. However, only one of those transistors actually generates and outputs a current. Accordingly, a gate potential is applied to any one of the PMOS transistor and the NMOS transistor, and a current is taken from any one of the PMOS transistor and the NMOS transistor according to the code data applied at the same time with the gate potential. Comparing the current source circuits connected to the intermediate electrode N7 between FIG. 4 and FIG. 7, in the circuits of FIGS. 4A and 4B, a current flows through the NMOS transistor Q4 and the PMOS transistor Q7 and the electric power is consumed irrespective of the magnitude of the current. I1 and the current I2. Meanwhile, in the circuit of FIG. 7B, the current does not flow through an NMOS transistor Q27 when the PMOS transistor Q22 is switched on to output a current. The PMOS transistor Q22 consumes electric power by the flowing current (I2−I1), and an amount thereof is smaller than a total amount of consumed electric power of the NMOS transistor Q4 and the PMOS transistor Q7. Electric power consumption of the NMOS transistor Q23 is zero.

The organic EL device in which three layers of the organic EL devices EL1, EL2, and EL3 in respective colors of R, G, and B are stacked has been described above, but the present invention is applicable to an appropriate organic EL device in which a plurality of layers are stacked. The directions of the currents need to be aligned in the all layers, but may be upward or downward with respect to the substrate. An order of the stacked layers and an outer electrode to be grounded may be appropriately selected. Colors are appropriately combined as well, and a structure in which white is added to R, G, and B is possible.

In the stacked type light-emitting device described above, one of a pair of outer electrodes (uppermost layer and lowermost layer which are in contact with the light-emitting layer) is fixed to a fixed voltage, while the other thereof is connected to the unidirectional current source. A current flowing from the unidirectional current source flows through the endmost light-emitting layer, and the net current applied from two current sources is added to the intermediate electrode or is subtracted therefrom, with the result that the current which flows through the next light-emitting layer is determined. The bidirectional current sources in opposite directions to each other are connected in parallel to the intermediate electrode, which enables currents corresponding to the provided luminances to flow through the respective light-emitting layers irrespective of the magnitude of the currents which flow through the first light-emitting layer and the second light-emitting layer.

### Third Embodiment

In the stacked type light-emitting devices according to the first embodiment and the second embodiment of the present invention, two outer electrodes are respectively connected to the voltage source and the current source. As a stacked type light-emitting device which has a simpler structure, Japanese Patent Application Laid-Open No. 2005-174639 proposes a stacked type light-emitting device in which two outer electrodes are short-circuited. In this embodiment, a bidirectional, current source is connected to the intermediate electrode of the stacked type organic EL device as described above. When the bidirectional current source is connected to the intermediate electrode, luminances of the organic EL devices thereabove and therebelow can be respectively controlled even in a case where the outer electrodes are short-circuited to be fixed to a fixed voltage.

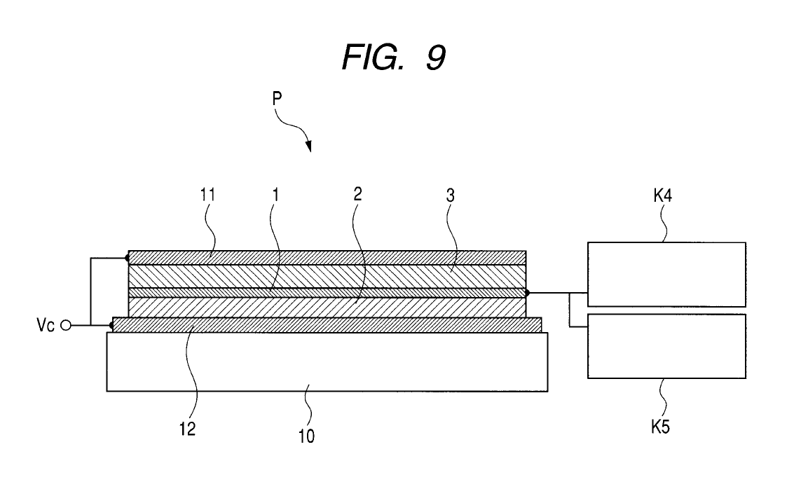

FIG. 9 is a sectional view of the stacked type light-emitting device to which this embodiment is applied.

The pixel P has a structure in which the light-emitting devices EL1 and EL2 of two colors are stacked on the substrate 10. The combination of the two layers may be any one of red and blue, red and green, and blue and green. The respective light-emitting devices are organic electroluminescence (EL) devices and have diode characteristics, in which a current flows from the top to the bottom thereof to emit light. A pair of the outer electrode 102 (which is close to the substrate) and the outer electrode 106a (which is far from the substrate), and the intermediate electrode 106 are disposed so that the light-emitting devices EL1 and EL2 are independently driven. Note that reference symbols of FIG. 9 are the same as those of the light-emitting device of FIG. 2, in which the upper layer is removed from the hole transport layer 103b of the third light-emitting device EL3.

The pair of outer electrodes 102 and 106a are short-circuited to be connected to the power source Vc, and the intermediate electrode 106 positioned in a center portion of the stacked type light-emitting device is connected to the two drive circuits K4 and K5. Two light-emitting devices EL1 and EL2 are equivalent to a diode in which two terminals are connected in parallel so that directions thereof are opposite to each other.

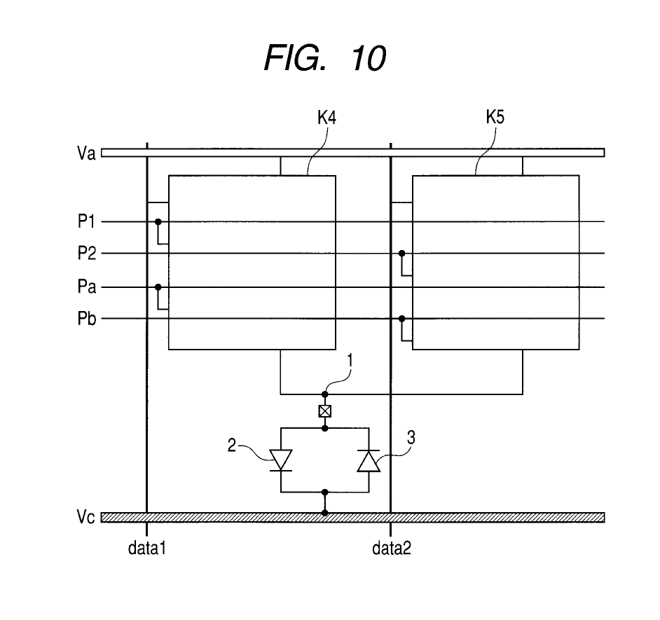

FIG. 10 is a diagram illustrating arrangements of the stacked type light-emitting device and the drive circuits of FIG. 9. The diodes EL1 and EL2 connected opposite in direction to each other correspond to the light-emitting devices stacked in two layers of FIG. 4, and the two diodes are included in one pixel. Two drive circuits K4 and K5 supply currents opposite in direction to each other to the intermediate electrode 106. The drive circuits K4 and K5 are provided for each pixel P. The drive circuits K4 and K5 and the stacked type light-emitting devices EL1 and EL2 form one pixel P.

In the pixel P, there are provided two scanning lines P1 and P2, two light-emitting control lines Pa and Pb, two data lines data_1 and data_2, a power source line Vc connected to an upper electrode and a lower electrode of the light-emitting device, and a power source line Va for the drive circuits K4 and K5. The scanning line P1 and the light-emitting control line Pa are connected to the drive circuit K4, while the data line data_2, the scanning line P2, and the light-emitting control line Pb are connected to the drive circuit K5. Note that in FIG. 1, the scanning lines P1 and P2 and the light-emitting control lines Pa and Pb are collectively represented by one scanning line R, and the data lines data_1 and data_2 are collectively represented by one data line D.

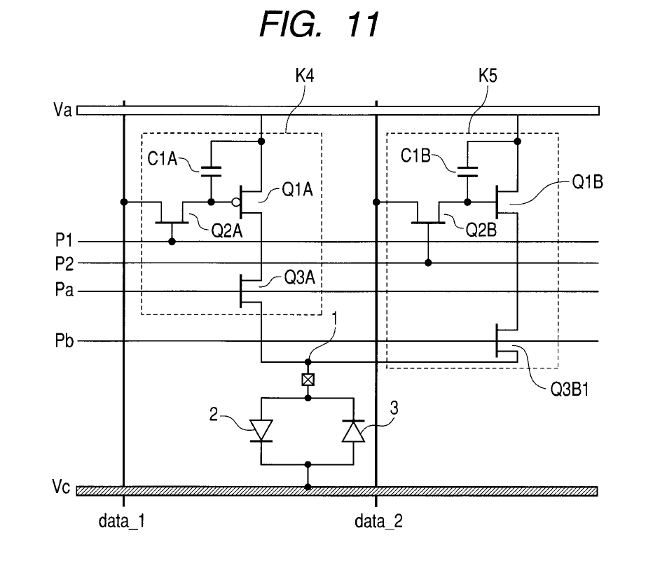

FIG. 11 specifically illustrates the drive circuits K4 and K5 of FIG. 10.

The drive circuit K4 includes a switching transistor (switch Q2A) which is turned on in response to a selection signal of the scanning line P1, a capacitor CIA, a P-channel type drive transistor Q1A, and another switching transistor (switch Q3A) which is turned on in response to a selection signal of the scanning line Pa. The drive circuit K5 includes a switching transistor Q2B which is turned on in response to a selection signal of the scanning line P2, a capacitor C1B, an N-channel type drive transistor Q1B, and another switching transistor Q3B which is turned on in response to a selection signal of the scanning line Pb.

The drive transistors Q1A and Q1B and the switching transistors Q3A and Q3B which are turned on in response to the selection signals of the light-emitting control lines Pa and Pb, respectively, convert held voltages of the holding capacitors CIA and C1B into currents and sequentially supply the currents to the light-emitting devices of a light-emitting portion.

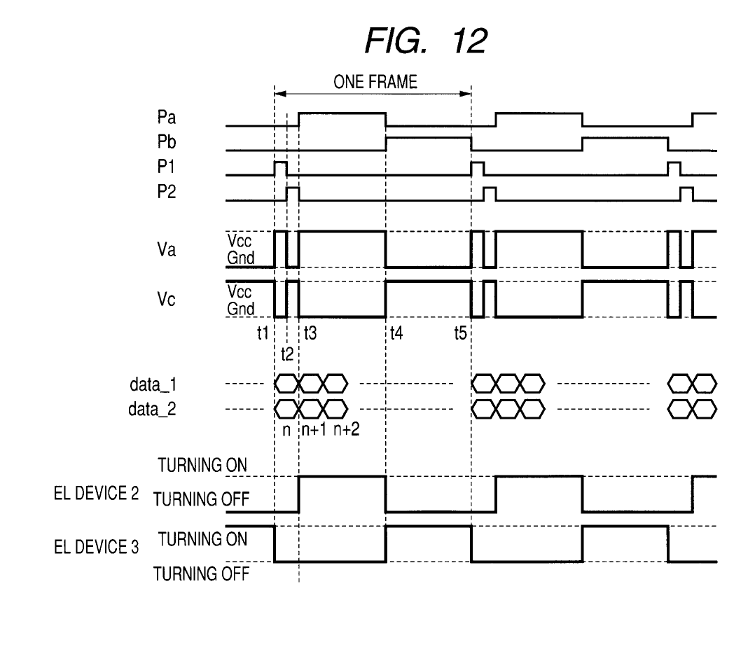

FIG. 12 is a timing chart showing operations of the drive circuits K4 and K5. Reference symbols provided to the left of respective voltage waveforms of FIG. 12 correspond to the signals transmitted by the lines having the same reference symbols in FIG. 11.

In FIG. 12, reference symbols Pa, Pb, P1, P2, Va, and Vc denote a scanning line, a light-emitting control line, and a power source line of n-th row. A programming period is from t1 to t3, a light-emitting period of a light-emitting device 2 is from t3 to t4, and a light-emitting period of a light-emitting device 3 is from t4 to t5.

In respective lines of following (n+1)-th row and (n+2)-th row, the same waveform is applied with a lag of one-unit data signal.

The scanning lines P1 and P2 are subsequently applied with the selection signal (level H), which form a continuous programming period t1 to t3. The data signals of the data lines data_1 and data_2 are input with a constant data signal, and subsequently, image signals of (n+1)-th row, (n+2)-th row, . . . , are transmitted in time series.

During the programming period (from t1 to t3) of one row, the data signal is held by the holding capacitors CIA and C1B of the respective pixels in the row through the procedure described below.

During a first half period (from t1 to t2) of the programming period (from t1 to t3), voltages of the power sources Va and Vc are set as Va=Vcc and Vc=GND, respectively. During this period, the selection signal (level H) is applied to the scanning line P1 to turn on the switch Q2A of the drive circuit K4, with the result that the holding capacitor CIA is charged with the image signal from the data line data_1.

During a latter half period (from t2 to t3) of the programming period, the voltages of the power sources Va and Vc are switched to be set as Va=GND and Vc=Vcc, respectively. During this period, the selection signal is applied to the scanning line P2 to turn on the switch Q2B of the drive circuit K5, with the result that the holding capacitor C1B is charged with the image signal from the data line data_2.

A period from t3 to t5 after the expiration of the programming period is a light-emitting period.

During a first half period (from t3 to t4), the voltages of the power sources Va and Vc are Vcc and GND, respectively, and the light-emitting control line Pa is applied with the selection signal (level H). Accordingly, the switch Q3A is turned on, and a current flows from the drive transistor Q1A to the organic EL light-emitting device 2 of a light-emitting portion, whereby the organic EL light-emitting device 2 emits light. At this time, the switch Q3B1 is turned off, and thus the organic EL light-emitting device 3 is in a light out state.

During the latter half period from t4 to t5, the voltages of the power sources Va and Vc are Vcc and Gnd, respectively, and the light-emitting control line Pb is applied with the selection signal (level H). Accordingly, the switch Q3B1 is turned on, and a current flows from the organic EL light-emitting device 3 to the drive transistor Q1B, with the result that the organic EL light-emitting device 3 emits light. At this time, the switch Q3A is turned off, whereby the organic EL light-emitting device 2 is in a light out state.

The above-mentioned periods from t1 to t5 are repeated for each frame.

During one frame period, two of the video signals are supplied from the data lines data_1 and data_2 to the pixels within one programming period (t1 to t3), and programmed into each of the drive circuits K4 and K5. The programmed voltages are held by the holding capacitor of each of the drive circuits K4 and K5. The drive circuits K4 and K5 use the voltages of the power sources Va and Vc and the signals from the light-emitting control lines Pa and Pb, to thereby cause the light-emitting devices EL1 and EL2 to sequentially emit light. In this manner, two colors are sequentially displayed in the different time periods, to thereby create a synthesized color image.

The power sources Va and Vc are alternately switched in potential at a timing when the first light-emitting period shifts to the second light-emitting period, to thereby change the polarity of a voltage to be applied to the current source and the organic EL devices. Those timings are common to the pixels in the row direction, and therefore the power supply voltage is reversed with respect to all the pixels arranged in the row direction simultaneously. For this reason, in FIG. 11, the power sources Va and Vc are both provided in parallel with the scanning line.

The power sources Va and Vc are alternately switched between Vcc and GND, and therefore only Vcc is required as an actual voltage source. Vc may be fixed to GND and Va may be switched between +Vcc and −Vcc, which is not desirable in that it is necessary to provide two voltage sources, that is, a positive source and a negative source, with the result that the number of the power sources is increased.

The light-emitting periods for two colors may be the same in length. However, as in the case of the light-emitting devices, when there is a significant variation in efficiency among the light-emitting devices according to the color thereof, the ratio of the light-emitting periods may be changed to thereby adjust the white balance.

The light-emitting control lines Pa and Pb are controlled to provide a light out state (L state) for a certain period in each of the light-emitting periods, thereby enabling adjusting the entire luminance.

The number of the light-emitting devices to be stacked is not limited to two. There may be provided a pixel which includes three stacked layers of RGB for emitting the three colors in a time-division manner. In this case, the video signals for the three colors are programmed in one programming period, and lights having the respective colors of RGB are sequentially emitted in the following three light-emitting periods.

### Fourth Embodiment

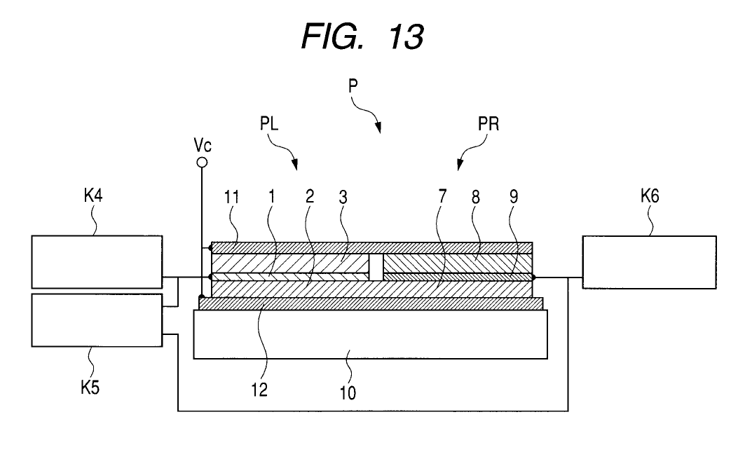

The stacked type light-emitting device illustrated in FIG. 9 includes two of the organic EL light-emitting layers and therefore is capable of emitting light in two colors. To display a color image in three colors of RGB, it is necessary to provide three light-emitting layers in one pixel. FIG. 13 illustrates an example of a pixel structured as described above.

The stacked type light-emitting device P illustrated in FIG. 13 includes two sets of the stacked type light-emitting devices illustrated in FIG. 9 formed in parallel with each other on the substrate. In addition to the light-emitting device 2 and 3 and the drive circuits K4 and K5 for driving the light-emitting device 2 and 3, there are disposed the light-emitting devices 7 and 8 and the drive circuit K6.

Similarly to the light-emitting devices 2 and 3, the light-emitting devices 7 and 8 are organic electroluminescence (EL) devices stacked in two layers, and are provided with diode characteristics. The light-emitting devices 7 and 8 emit light when supplied with current which flows therethrough from top to bottom, which is the same direction as in the case of the light-emitting devices 2 and 3. Three layers of electrodes, that is, a top surface electrode 11, a bottom surface electrode 12, and an interlayer electrode 9 are disposed for the light-emitting devices 7 and 8.

The outer electrode 11 in the uppermost layer and the outer electrode 12 in the bottom layer are shared by the pair of the light-emitting devices 2 and 3, and are short-circuited to be connected to the power source Vc. The intermediate electrode 9 in the middle is electrically separated from another intermediate electrode 1, and connected to the drive circuits K6 and K5. The light-emitting devices 7 and 8 share the drive circuit K5 with the pair of the light-emitting devices 2 and 3.

The pair of the light-emitting devices 2 and 3 and the pair of the light-emitting devices 7 and 8 are formed in a region PL and a region PR, respectively, which are obtained by dividing the area of one pixel P. The two regions PL and PR form one pixel P.

The light-emitting device 2 is the red (R) light-emitting device, the light-emitting device 7 is a green (G) light-emitting device, and the light-emitting device 3 and the light-emitting device 8 each are a blue (B) light-emitting device. As described above, the two regions PL and PR each include the light-emitting device pair formed therein, the light-emitting device pair including stacked layers of two colors of the three primary colors of RGB. The combinations of the two colors are different between the two regions PL and PR. With this configuration, the pixel according to this embodiment has a structure capable of attaining a full-color display apparatus.

The regions PL and PR include four light-emitting devices in total. Two of the four light-emitting devices are in the same color, and therefore may be formed in a common light-emitting layer. In FIG. 13, the light-emitting devices 2 and 7 are formed in the same light-emitting layer. Those layers may emit light simultaneously, and therefore may share one drive circuit. The drive circuit K5 shared by the two regions is a circuit for driving the light-emitting devices sharing the common light-emitting layer.

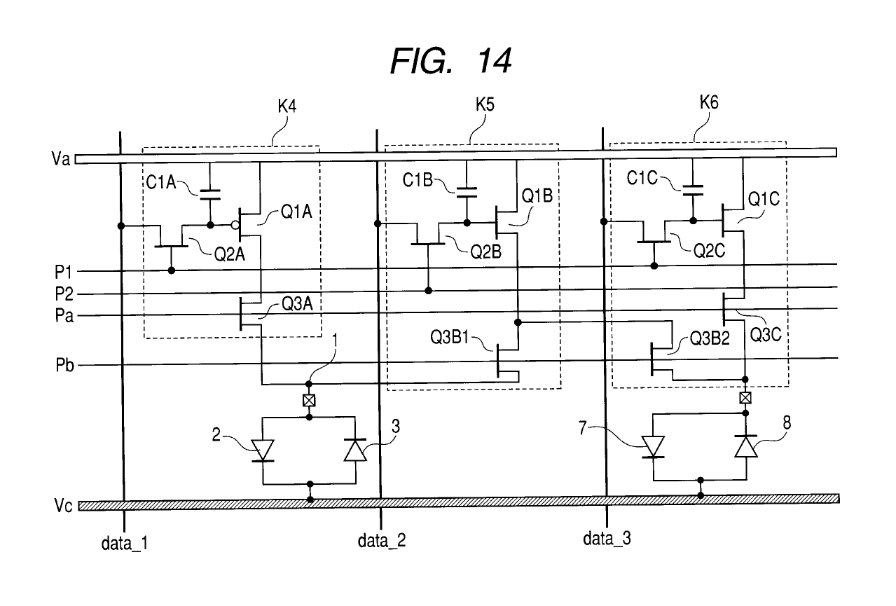

FIG. 14 is a diagram illustrating the circuit configuration of the pixel illustrated in FIG. 13. The portions that operate similarly to those of FIG. 10 are denoted by the same reference numerals.

The drive circuit K4 receives a video signal from the data line data_1, and supplies current to the R light-emitting device 2 during the light-emitting period.

The drive circuit K5 receives a video signal from the data line data_2, and supplies current simultaneously to both of the B light-emitting devices 3 and 8 in the two regions, during the light-emitting period.

The drive circuit K6 receives a video signal from the data line data_3, and supplies current to the G light-emitting device 7 during the light-emitting period.

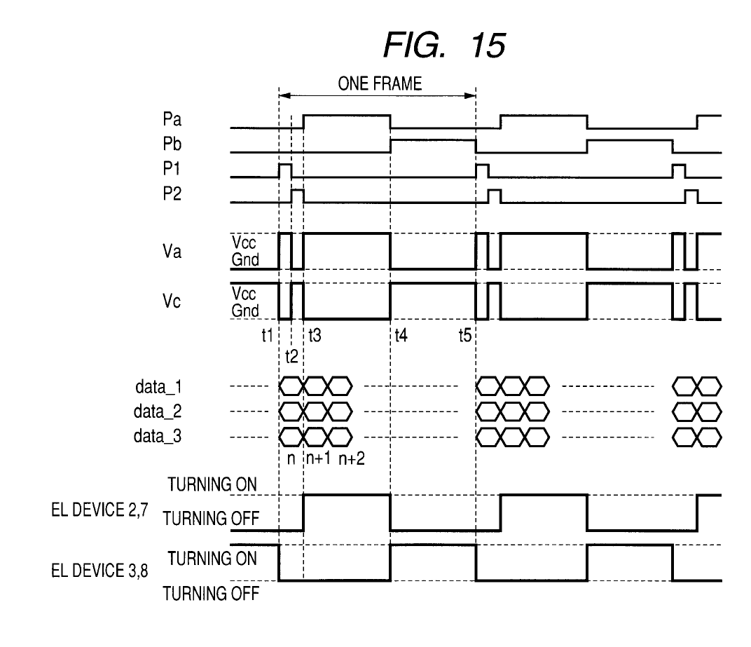

FIG. 15 is a timing chart for describing an operation of the circuit of FIG. 14.

In the first half (t1 to t2) of the programming period, the power supply voltages are set as Va=Vcc and Vc=GND. The selection signal (level H) is applied to the scanning line P1, to thereby bring the switching transistors Q2A and Q2C into conduction. The red (R) video signal is supplied to the drive circuit K4 from the data line data_1, and held by the holding capacitor CIA. At the same time, the green (G) video signal is supplied to the drive circuit K6 from the data line data_3, and held by the holding capacitor C1C.

In the latter half (t2 to t3) of the programming period, the power supply voltages are set as Va=GND and Vc=Vcc. The selection signal (level H) is applied to the scanning line P2, to thereby bring the switching transistor Q2B into conduction. The blue (B) video signal is supplied to the drive circuit K5 from the data line data_2, and held by the holding capacitor C1B.

After the expiration of the programming period, in the first half (t3 to t4) of the light-emitting period, the power supply voltages are set as Va=Vcc and Vc=GND. The light-emitting control line Pa reaches the level H, and the switching transistors Q3A and Q3C are brought into conduction. The drive current for the drive transistors Q1A flows in a direction from Va to Vc, and therefore the current all flows through the R light-emitting device 2, and no current flows through the B light-emitting device 3. Similarly, the drive currents for the drive transistors Q1C are only supplied to the G light-emitting device 7, and no current flows through the B light-emitting device 8. As a result, an image in colors of R and G is displayed.

In the latter half (t4 to t5) of the light-emitting period, the power supply voltages are set as Va=GND and Vc=Vcc. The control line Pb reaches the level H, and the switching transistors Q3B1 and Q3B2 are brought into conduction. As a result, the B light-emitting devices 3 and 7 are supplied with current from the drive transistors Q1B. The current flows in a direction from Vc to Va, and therefore the current does not flows through the R light-emitting device 2 and the G light-emitting device 7. The current only flows through the B light-emitting devices 3 and 8, with the result that an image in blue color is displayed.

The displayed image in R and G obtained in the first half of the light-emitting period and the displayed image in B obtained in the latter half of the light-emitting period are synthesized, whereby a color gray-scale image is displayed.

The ratio of the light-emitting period may be changed in consideration of the efficiency of the light-emitting device. Furthermore, the combinations of the colors of the light-emitting devices 2, 3, 7, and 8 are not limited to the colors described above, and arbitrarily determined. One of the light-emitting devices forming a pair and being connected in parallel may be a light-emitting device which is more susceptible to degradation as compared with the other one of the light-emitting devices.

### Fifth Embodiment

In the pixel configuration illustrated in FIG. 11 and FIG. 14, the power source lines Va and Vc are alternately switched in voltage between a positive voltage (+Va) and a ground potential (GND), to thereby generate current in the drive circuits K4, K5, and K6. When Va is a positive voltage and Vc is grounded, current is generated in the drive circuits K4 (and K6), and flows through the light-emitting devices 2 (and 7). When Va is grounded and Vc is a positive potential, current is generated in the drive circuit K5, and flows through the light-emitting devices 3 (and 8).

The programming period is divided into two periods of t1 to t2 and t2 to t3, and the programming is independently performed in each of the periods. The reason for this is that it is necessary to switch the power supply voltage at the time of programming because the charging voltage of the holding capacitor C1A uses Vcc as a reference, while the charging voltage of the holding capacitor C1B uses GND as a reference.

Instead of providing one power source line and changing the voltage thereof, there may be provided two power source lines each applying a fixed voltage.

When the power sources for the drive circuits K4 and K5 are set to different potentials (+Va and GND), two video signals data_1 and data_2 may be programmed simultaneously.

According to this embodiment, the present invention is applied to stacked type light-emitting devices having different fixed voltage power sources.

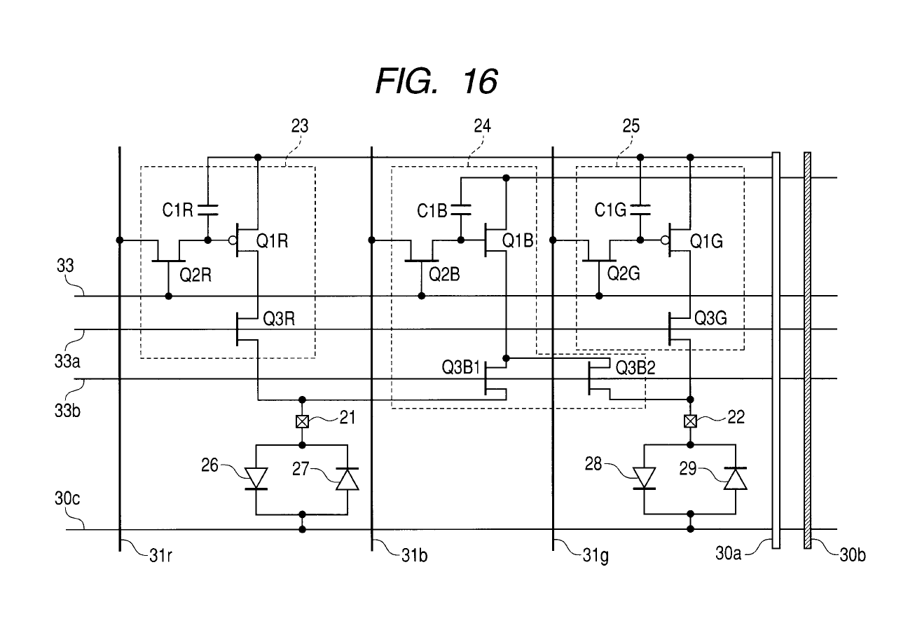

FIG. 16 illustrates a circuit in which the power source line Va of the drive circuit of FIG. 14 is replaced by two power source lines 30a (output voltage=+Va) and 30b (output voltage=GND) each outputting a fixed voltage.

Organic EL devices 26 to 29 are stacked type light-emitting devices each having a cross section similar to that of FIG. 13, in which the outer electrodes are short-circuited. The organic EL device 26 emits red light, the organic EL device 28 emits green light, and the organic EL devices 27 and 29 emit light in the same color of blue. The colors of light emitted from the respective layers are not limited thereto, and any arrangement may be adopted as long as the four light-emitting devices emit three primary colors of R, G, and B.

The organic EL devices 26 to 29 and drive circuits 23, 24, and 25 collectively form one pixel P which emits light in three colors of R, G, and B.

An intermediate electrode 21 of the organic EL devices 26 and 27 is connected to the drive circuits 23 and 24 through the switches Q3R and Q3B1. Similarly, an intermediate electrode 22 of the organic EL devices 28 and 29 is connected to the drive circuits 24 and 25 through the switches Q3B2 and Q3G.

The outer electrode of the organic EL devices 26 and 27, and the outer electrode of the organic EL devices 28 and 29 are both connected to a third power source line 30_{c}.

The two intermediate electrodes 21 and 22 share the drive circuit 24. The drive circuit 24 supplies current to the organic EL devices 27 and 29 of the same color (blue). The current flowing through each of the organic EL devices 27 and 29 is approximately half of the current flowing through the drive transistor Q1B. It should be noted that the light-emitting devices 27 and 29 each may be provided with an independent drive circuit, without sharing a drive circuit. Furthermore, the organic EL devices 26 and 27 may be two organic EL devices connected so as to provide current for emitting light in directions mutually opposite to that of the intermediate electrode 21. The same applies to the organic EL devices 28 and 29.

The drive circuit 23 includes the switch Q3R, a drive transistor Q1R, a capacitor C1R, and a switch Q2R. The drive transistor Q1R has one of the main electrodes (drain) connected to the switch Q3R and the other one of the main electrodes (source) connected to the power source line 30a (which has a positive potential with respect to the potential of a power source 30c). The capacitor C1R and the switch Q2R are each connected to the control electrode (gate) of the drive transistor Q1R. The capacitor C1R is connected between the control electrode of the drive transistor Q1R and the power source line 30a. The drive transistor Q1R includes a P-type MOS transistor, the switches Q3R and Q2R each include an N-type MOS transistor.

The drive circuit 25 is similar in configuration to the drive circuit 23.

The drive circuit 24 includes the two switches Q3B1 and Q3B2, the drive transistor Q1B, the capacitor C1B, and the switch Q2B. The drive transistor Q1B has one of the main electrodes (drain) connected to the switches Q3B1 and Q3B2 and the other one of the main electrodes (source) connected to the power source line 30b (which has a negative potential with respect to the potential of the power source 30c). The capacitor C1B and the switch Q2B are each connected to the control electrode (gate) of the drive transistor Q1B. The capacitor C1B is connected between the control electrode of the drive transistor Q1B and the power source line 30b. The switches Q3B1 and Q3B2 and the drive transistor Q1B each include an N-type MOS transistor.

Data lines 31ᵣ, 31_{g}, and 31_{b} connected to the switches Q2R, Q2G, and Q2B respectively transfer data of R, G, and B to the pixel.

One scanning line R of the matrix display apparatus illustrated in FIG. 1 is formed of three control lines 33, 33ₐ, and 33_{b} in FIG. 16.

The control line 33 is connected to each of the gates of the switches Q2R, Q2B, and Q2G, and closes the switches simultaneously, to thereby transfer data in the data line to the capacitor of each of the drive circuits.

The control line 33ₐ is connected to the control terminal of the switches Q3R and Q3G, and opens and closes the switches simultaneously based on the signal from the control line 33ₐ. When the switches are closed, current flows through the organic EL devices 26 and 28 from the drive circuits 23 and 25, and red light and green light are emitted with a luminance corresponding to the current. At this time, the organic EL devices 27 and 29 are in a reverse-biased state, and current does not flow therethrough.

The control line 33_{b} is connected to the control terminal of the switches Q3B1 and Q3B2, and opens and closes the switches simultaneously based on the signal from the control line 33_{b}. When the switches are closed, substantially the same amount of current flows through the organic EL devices 27 and 29 from the drive circuit 24, and blue light is emitted with a luminance corresponding to the current. At this time, the organic EL devices 26 and 28 are in a reverse-biased state, and current does not flow therethrough.

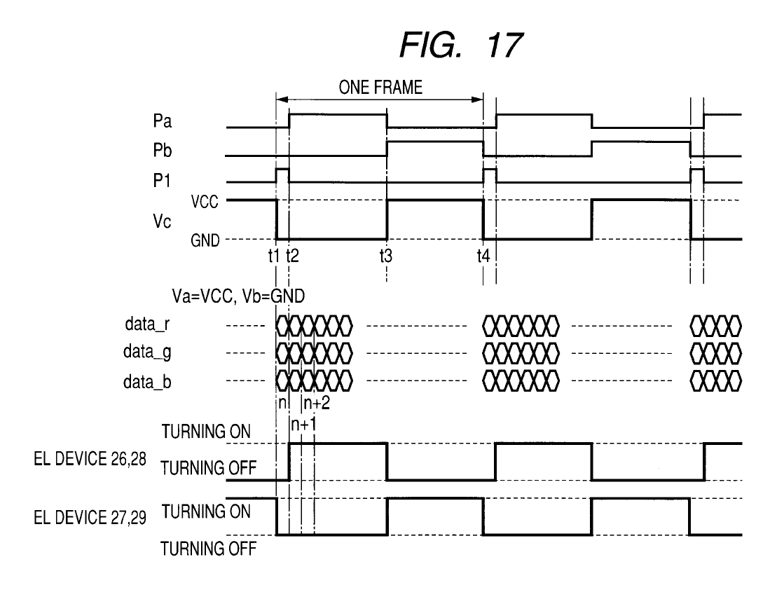

FIG. 17 is a timing chart illustrating an operation of the drive circuits of FIG. 16. Pₐ, P_{b}, and P₁ correspond to the scanning signals respectively applied to the control lines 33ₐ, 33_{b}, and 33₁ of FIG. 16. Vc refers to the voltage signal to be applied to the power source line 30_{c}. Furthermore, Va refers to the output voltage of the power source line 30a, and is fixed to Vcc. Vb refers to the output voltage of the power source line 30b, and is fixed to the GND potential.

In the period T₁ (programming period) from time t1 to time t2, the scanning signal P₁ applied to the control line 33 reaches a high level, and the switches Q2R, Q2B, and Q2G of the drive circuits 23, 24, and 25 are turned ON. As a result, the video signals (image signals) data_r, data_b, and data_g to be supplied respectively to the data lines 31ᵣ, 31_{b}, and 31_{g} are charged in the capacitors C1R, C1B, and C1G. In this manner, the control potential (gate potential) for determining the potential of the current to flow through the organic EL devices within the first and second light-emitting periods is held in the capacitors C1R, C1B, and C1G. This programming operation is performed for every pixel rows, and when the programming is completed for one pixel row, the programming is performed for the next pixel row. The data lines 31ᵣ, 31_{b}, and 31_{g} are each applied with a video signal (image signal) for the pixel row within the period T₁ (from time t1 to time t2 of FIG. 17) for programming one pixel row. After that, to program the next pixel row, a video signal for programming the next pixel row is applied for the period same in duration as the period T₁.

In the period T₂ (first light-emitting period) from time t2 to time t3, the scanning signal Pa applied to the control line 33ₐ turns ON the switches Q3R and Q3G. The voltage Vc is set to GND potential, whereby current flows through from the drive circuits 23 and 25 connected to the power source Va of positive voltage to the intermediate electrodes 21 and 22, and the organic EL devices 26 and 28 emit light upon receiving the current as the forward direction current.

In the period T₃ (second light-emitting period) from time t3 to time t4, the scanning signal Pb applied to the control line 33_{b} turns ON the switches Q3B1 and Q3B2. The voltage Vc is set to Vcc, whereby the drive circuit 24 connected to the power source line Vb at GND potential supplies current in a direction drawn out from the intermediate electrodes 21 and 22, whereby the organic EL devices 27 and 29 emit light upon receiving the current as the forward direction current.

As described above, the respective drive circuits capture the video signal from the data line and hold the signal in the capacitor, to thereby generate current based on the signal thus held. Accordingly, current generated by each of the drive circuits is supplied to the two light-emitting devices as the drive current therefor, and the luminance of the respective light-emitting devices is controlled.

In each of the drive circuits, the current flowing through the light-emitting device is controlled through ON/OFF operation of the switch provided between a P-type or N-type MOS transistor and the common terminal, whereby two light-emitting devices connected in parallel to each other emit light in different periods.

According to this embodiment, the fixed voltage source 30a which supplies power to the current sources 23 and 25 supplying current in a direction toward the intermediate electrodes 21 and 22, and the fixed voltage source 30b which supplies power to the current source 24 supplying current in a direction drawn out from the intermediate electrodes 21 and 22 are separately provided. The potentials of the fixed voltage source 30a and the fixed voltage source 30b are fixed to Vcc and GND, respectively, which makes it possible to program a video signal to the power sources simultaneously. Furthermore, during the light emission, the potential of the opposite electrode Vc of the organic EL device is switched between +Vcc and GND, which requires a single voltage source (Vcc).

### (Time-Sharing Light Emission)

In the stacked type light-emitting apparatus according to the third to fifth embodiments of the present invention, the stacked two light-emitting layers emit light in different colors in order of time. There are provided three data lines for respective colors which provide video signals, and the video signals of the respective colors are simultaneously programmed in the pixel of the selected row in one programming period. There are three light-emitting periods along the respective colors, during which light emission of each color is performed in sequence. Despite that an image in a single color is displayed in each of the light-emitting period, the switchover of the periods is fast enough to allow each image in a single color to be temporally synthesized so as to be visually recognized as a color image.

There may be provided only one data line to provide a signal in a time-dividing manner to the drive circuit of each color. With such a structure, however, the light-emitting period is shortened, leading to a low luminance.

Each of the drive circuits is provided with the holding capacitor for holding the video signal. The data is stored in a memory of the holding capacitor after the programming, which causes no loss of data even if the light emitting order is postponed.

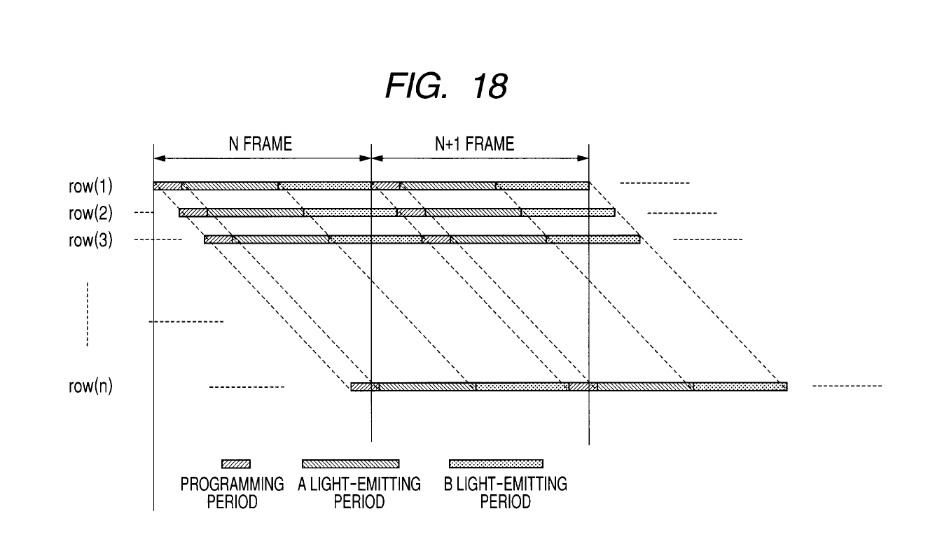

FIG. 18 is a diagram for illustrating the programming and a chronological sequence of the display timing in the display apparatus for emitting light in two colors, which has been described in the third embodiment.

The sequence of the programming and the light emission are repeated in a frame cycle.

Each of the rows from row(1) to row(n) is sequentially selected, and subjected to the programming. In the programming, two video signals are programmed with respect to two colors of A and B. After that, there is provided an A light-emitting period for emitting light in first color, which is followed by a B light-emitting period for emitting light in second color different from the first color.

Generally, the video signal is input to a display apparatus as a time-series signal for each color of RGB. In the display apparatus including the stacked organic EL devices in two colors described in the third to fifth embodiments, signals (referred to as A and B) are input to the display apparatus from an external circuit in parallel with a signal of another color. The video signals of A and B are captured in the drive circuit within one programming period, to thereby capture the video signals without using a frame memory or the like.

When adopted a system in which a frame memory is used to store a signal for a color to be emitted later (signal B), and the signals A and B are captured in the drive circuit respectively in different programming periods to perform light emission, the capacitor may be shared by the drive circuits for A and B, to thereby make the drive circuit compact. In this case, however, the programming and light emission for one color needs to be performed within a ½ frame period, and it is necessary to provide a memory for storing the signal A as well as the signal B.

According to this embodiment, two video signals of A and B existing in parallel with each other are programmed simultaneously in one programming period, and therefore it is not necessary to provide a memory for storing the video signal B for which the light-emitting period comes later. Furthermore, the programming can be performed within one frame period in synchronization with a video signal externally transmitted, which eliminates the need to store the image data obtained from the signal A.

To adjust the luminance of the light-emitting apparatus, a light out period may be provided in the light-emitting period of each color.

Furthermore, to eliminate flicker, the light-emitting period of each color within a frame period may be flashed at least twice or a plurality of times.

As for the ratio between the light-emitting periods (the first light-emitting period and the second light-emitting period) of the stacked two organic EL devices, in consideration of the efficiency of each of the two organic EL devices, the light-emitting period of the organic EL device of higher luminance may be set shorter while the light-emitting period of the organic EL device of lower luminance may be set longer. Furthermore, in a case where the degree of the characteristic change occurring in the organic EL devices having driven for a long time varies depending on the colors, the ratio between the light-emitting periods may be changed with time in consideration thereof.

### Modification Example 1 of the Drive Circuit

The drive circuit for supplying current to the organic EL devices is not limited to the drive circuits described in the first to fifth embodiments. Hereinbelow, a description is given of modification examples of the drive circuit. The circuits in below is described as the modification example of the drive circuit according to the fifth embodiment, however, the respective drive circuits 23 to 25 may be used as the current source in the first to fourth embodiments.

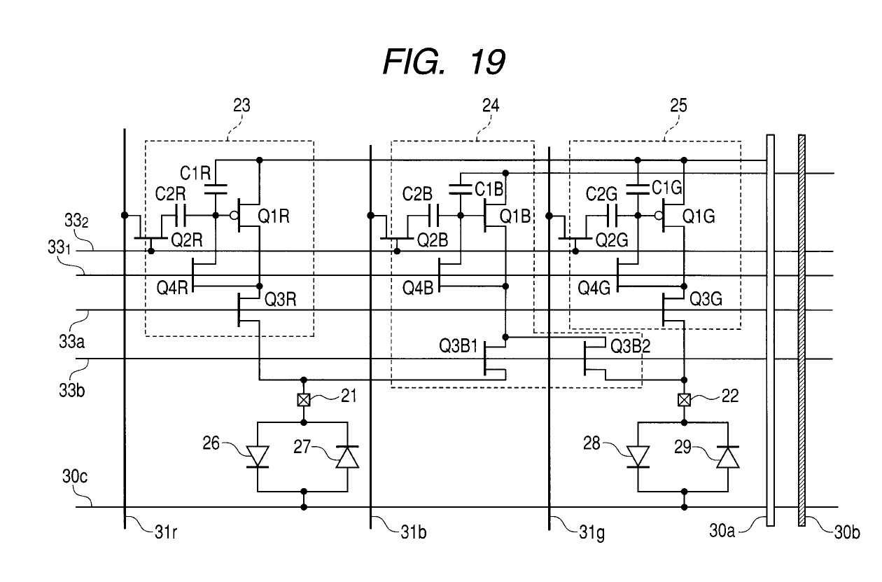

FIG. 19 illustrates a first modification example of the circuit illustrated in FIG. 16. The constituent elements same as those of FIG. 16 are denoted by the same reference symbols. The circuit is different from the circuit of FIG. 16 in that each of the drive circuits further includes a second capacitor C2, a switch Q4, and a control line 33₁ for the switch Q4. The second capacitor C2 is provided between the gate of the drive transistor Q2 and the data line 31, and connected in series with the switch Q4. The switch Q4 is provided between the gate and the drain of the drive transistor Q2. The control line 33 in FIG. 16 corresponds to the control line 33₂ in FIG. 19.

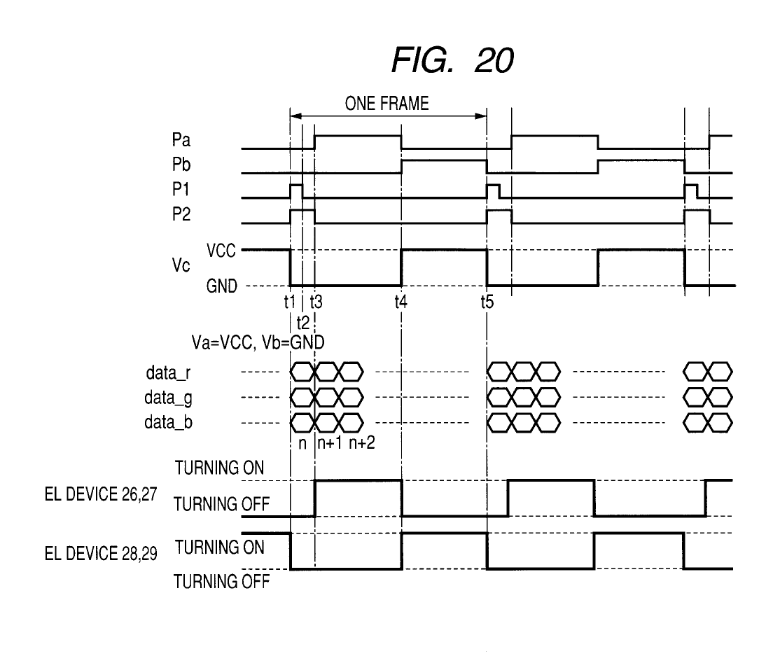

The operation of the drive circuit is described with reference to the timing chart of FIG. 20. The reference symbols correspond to the reference symbols in FIG. 17.

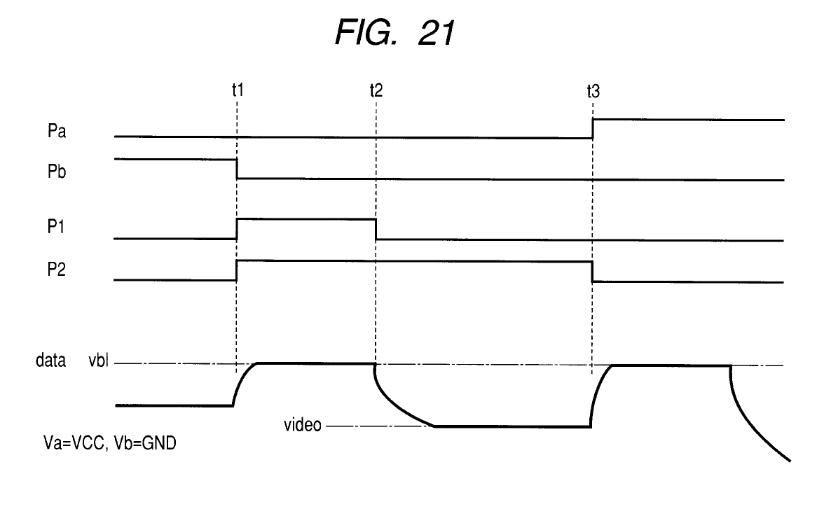

The control signal P₁ indicates the scanning signal to be supplied to the control line 33₁. Though not described in detail in FIG. 20, the voltages of the data lines data_r, data_b, and data_g are fixed to the reference potential during the period from t1 to t2, and during the period from t2 to t3, image data is provided. FIG. 21 is an enlarged diagram illustrating the voltages of the respective control lines and the voltages of the data lines during the period from t1 to t3.

During the period T₁ from time t1 to time t2, the scanning signal P₁ of the control line 33₁ and the scanning signal P₂ of the control line 33₂ are both on high levels, while the scanning signal Pₐ of the control line 33ₐ and the scanning signal P_{b} of the control line 33_{b} are both on low levels. As a result, the switches Q4R, Q4B, and Q4G are turned ON, to thereby short-circuit the drive transistors Q1R, Q1B, and Q1G between the gate and the drain thereof. Furthermore, the switches Q3R, Q3B1, Q3B2, and Q3G are turned off, to thereby shut off the current paths between the drive transistors Q1R, Q1B, and Q1G and the intermediate electrodes 21 and 22. In this state, the currents that have flowed through the drive transistors Q1R, Q1B, and Q1G flow into the capacitors C1R, C1B, and C1G via the short-circuited switch between the drain and the gate of each of the drive transistors Q1R, Q1B, and Q1G, whereby the charge accumulated in each of the capacitors is discharged. The discharge continues until the voltages of the capacitors C1R, C1B, and C1G are lowered, and the gate-source voltage of each of the drive transistors reaches the threshold value Vth. During this time, the scanning signal P₁ supplied to the control line 33₁ is on high level, and therefore the switches Q2R, Q2B, and Q2G are turned ON. Accordingly, the reference potential vbl to be applied to each of the data lines 31ᵣ, 31_{b}, and 31_{g} are transferred to one end of the capacitors C2R, C2B, and C2G. As a result, the capacitors C2R, C2B, and C2G are applied with a voltage obtained by adding the threshold voltage of each of the drive transistors to the difference between Vcc and the reference potential.

At time t2, the scanning signal P₁ of the control line 33₁ becomes low level, and the switches Q4R, Q4B, and Q4G are turned off. At the same time, the potentials of the data lines 31ᵣ, 31_{b}, and 31_{g} are shifted from the reference potential vbl to the video signal potential, along which the gate potentials of the drive transistors Q1R, Q1B, and Q1G change, with the result that the gate-source voltage increases from the threshold voltage Vth by the amount of the change. As a result, the drive transistors Q1R, Q1B, and Q1G each generate the drive current, which is unaffected by the variations in threshold value.

The operations in the light-emitting period from time t3 to time t4, and in the light-emitting period from time t4 to time t5 are similar to those in the fifth embodiment.

### Modification Example 2 of the Drive Circuit

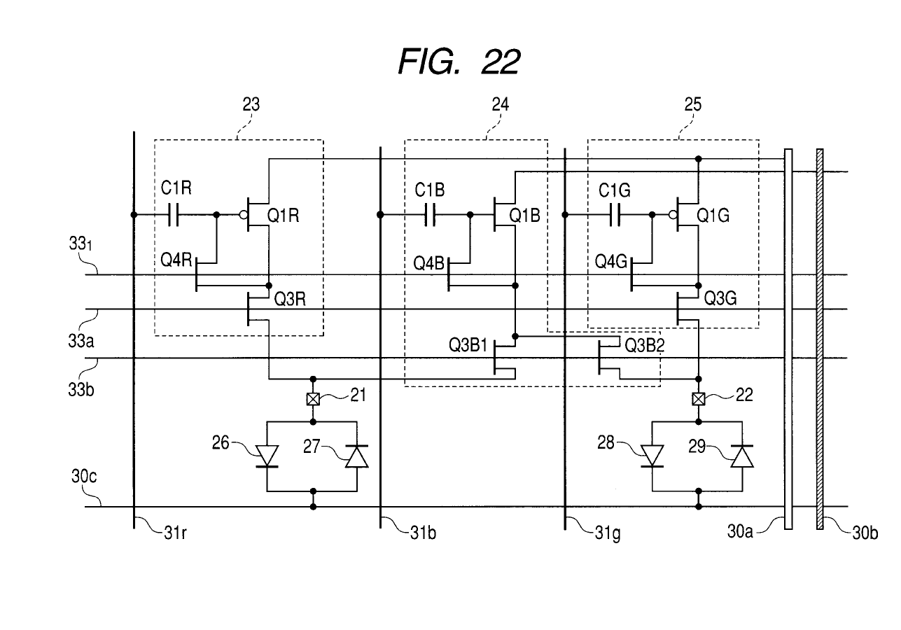

FIG. 22 illustrates a second modification example of the circuit according to the fifth embodiment of the present invention.

The circuit illustrated in FIG. 22 is different from the circuit of FIG. 16 in that the capacitors C1R, C1B, and C1G are disposed between the gates of the drive transistors Q1 and the data lines 31, the switches Q2R, Q2B, and Q2G and the control line 33 are omitted, and, similarly to the first modification example, the switches Q4R, Q4B, and Q4G are provided between the gate and drain of each of the drive transistors Q1, together with the control line 33₁ for controlling the switches.

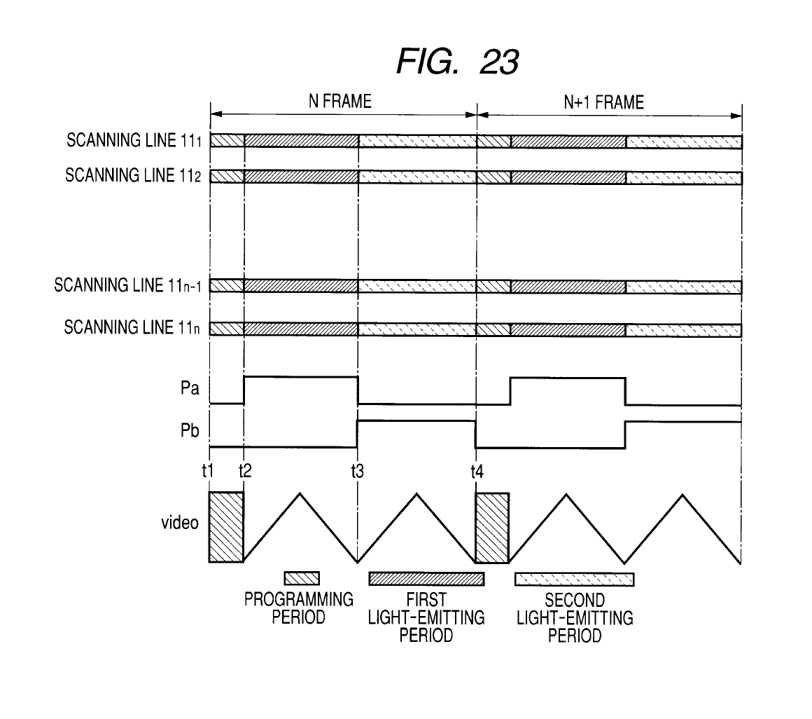

FIG. 23 is a timing chart illustrating the operations of the drive circuits of FIG. 22. P1(1) to P1(n) illustrate the voltages of the control line 33₁ in the rows 1 to n, respectively.

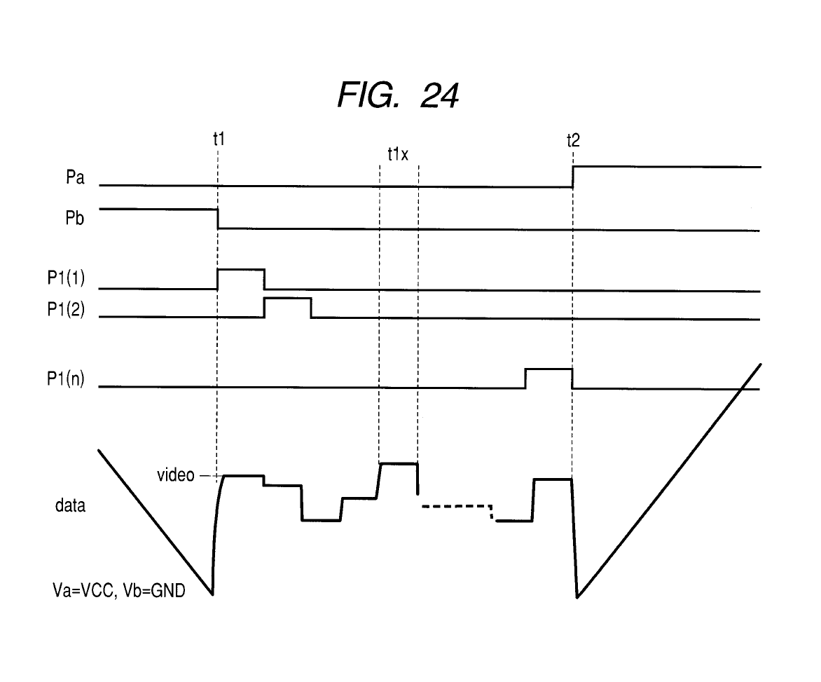

FIG. 24 illustrates in detail a period from time t1 to time t2 in the timing chart in FIG. 23.

During the period from time t1 to time t2, the scanning signals of P1(1) to P1(n) are sequentially applied to the control line 33₁ of the first row to the n-th row.

During the period T₁ from time t1 to time t2, the scanning signal Pₐ of the control line 33ₐ and the scanning signal P_{b} of the control line 33_{b} are both on low level. During the period t1x in the period T₁, any one of the scanning signals P1(x) (x=1 to n) is on high level, and in the drive circuits 23 to 25 of the pixel row, the switches Q4R, Q4B, and Q4G are turned ON to short-circuit the drive transistors Q1R, Q1B, and Q1G between the gate and the drain thereof. Furthermore, the switches Q3R, Q3B1, Q3B2, and Q3G are turned OFF, to thereby shut off the current paths between the drive transistors Q1R, Q1B, and Q1G and the intermediate electrodes 21 and 22. In this state, the current that has flowed through the drive transistors Q1R, Q1B, and Q1G flows into the capacitors C1R, C1B, and C1G via the short-circuited path between the drain and the gate of each of the drive transistors Q1R, Q1B, and Q1G. The current increases the gate potentials of the drive transistors Q1R and Q1G in the drive circuits 23 and 25, while in the drive circuit 24, the current decreases the gate potential of the drive transistor Q1B. The current continues to flow until the gate-source voltage of each of the drive transistors reaches the threshold value Vth. During this time, the voltage of each of the data lines 31ᵣ, 31_{b}, and 31_{g} is at the video signal potential video illustrated in FIG. 23. When the gate-source voltages of the drive transistors have reached the threshold values Vth, the capacitors C1R, C1B, and C1G each hold a voltage obtained by adding the threshold voltage of the drive transistors to the video signal potential.

During the period T₂ (first light-emitting period) from time t2 to time t3, the scanning signal Pa of the control line 33ₐ is on high level, and the switches Q3R and Q3G are turned ON, while the data lines 31ᵣ, 31_{b}, and 31_{g} are supplied with a delta-wave signal illustrated in FIG. 23. The gate potential of each of the drive transistors Q1R, Q1B, and Q1G changes in accordance with the delta-wave signal, and during the period in which the gate-source voltage is higher than the threshold voltage Vth, the drive current flows from the drive transistors Q1R and Q1G to the organic EL devices 26 and 28, whereby the organic EL devices 26 and 28 are brought into the light-emitting state.

During the period T₃ (second light-emitting period) from time t3 to time t4, the scanning signal Pb of the control line 33_{b} is on high level, and the switches Q3B1 and Q3B2 are turned ON, while the data lines 31ᵣ, 31_{b}, and 31_{g} are supplied with the delta-wave signal. The gate potential of each of the drive transistors Q1R, Q1B, and Q1G changes in accordance with the delta-wave signal, and during the period in which the gate-source voltage is higher than the threshold voltage Vth, the drive current is generated. The drive current generated by the drive transistor Q1B flows into the organic EL devices 27 and 29, to thereby cause the organic EL devices 27 and 29 to emit light.

The signal generated in the light-emitting period to be supplied to the data line is not limited to a delta-wave signal, and may be a rectangular-wave signal.

### Modification Example 3 of the Drive Circuit

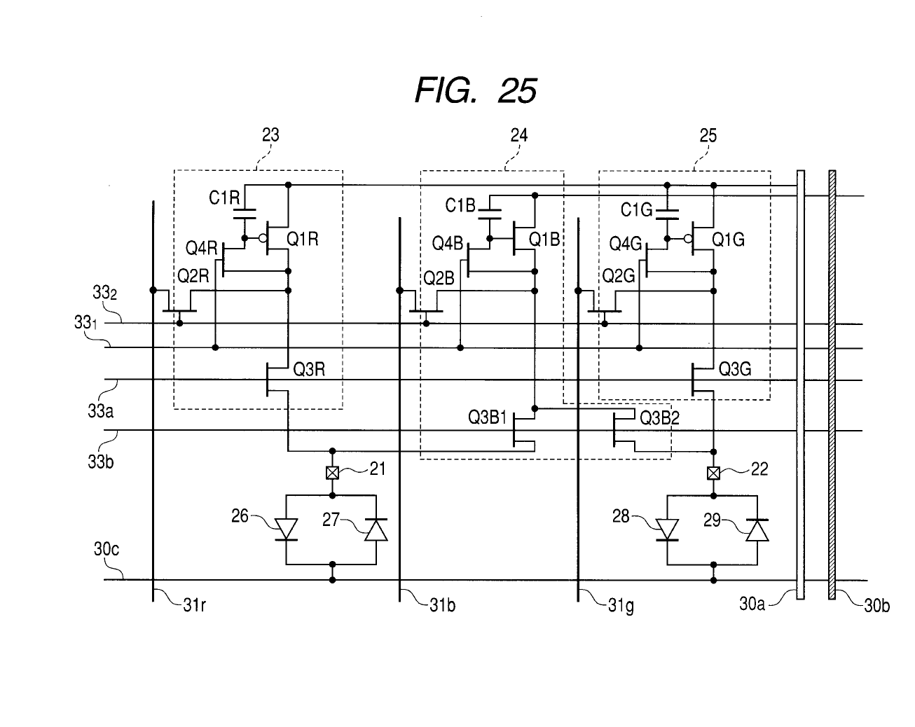

FIG. 25 illustrates a third modification example of the circuit according to the fifth embodiment of the present invention.

The circuit is different from the circuit of FIG. 16 in that the switches Q2R, Q2B, and Q2G serve as switches for connecting the drains of the drive transistors Q1 and the data line, and, similarly to the first modification, the switches Q4R, Q4B, and Q4G are provided between the gate and the drain of each of the drive transistors Q1, together with the control line 33₂ for controlling the switches.

Furthermore, the data lines 31ᵣ, 31_{b}, and 31_{g} are supplied, not with a voltage signal, but with a current signal generated by an external circuit (not shown).

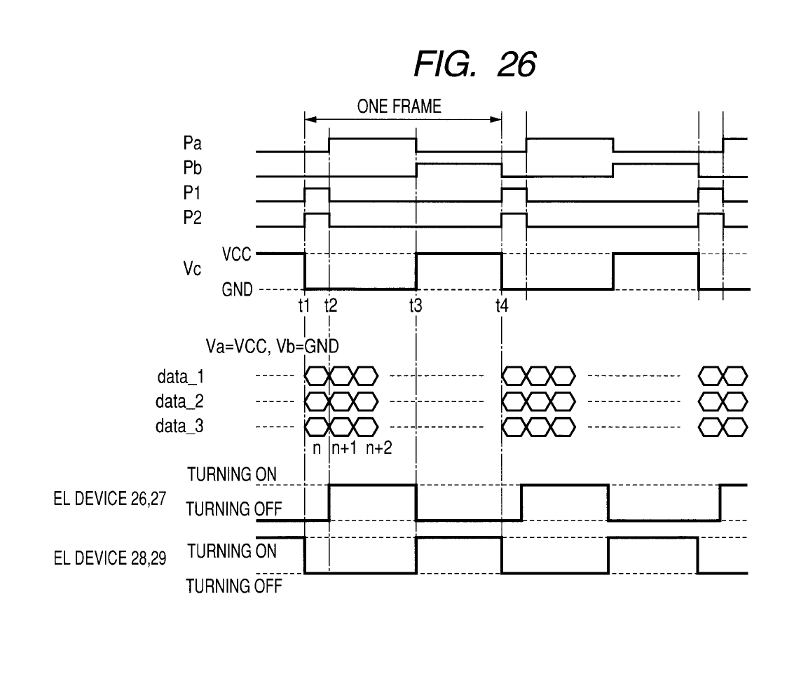

FIG. 26 is a timing chart illustrating the operation of the drive circuit illustrated in FIG. 25.

During the period T₁ from time t1 to time t2, the scanning signals P1 and P2 to be supplied to the control lines 33₁ and 33₂ are on high level, and the switches Q4R, Q4B, and Q4G and the switches Q2R, Q2B, and Q2G are turned ON. The drive transistors Q1R, Q1B, and Q1G are each short-circuited between the gate and the drain thereof, d also connected to the data lines 31ᵣ, 31_{b}, and 31_{g}, respectively. The current signals in the data lines 31ₐ, 31_{b}, and 31_{g} flow into the drive transistors Q1R, Q1B, and Q1G. Depending on the current signals, the gate-source potentials of the drive transistors are determined, and held by the capacitors C1R, C1B, and C1G.

The operations in the period from time t2 to time t3 and in the period from time t3 to time t4 are similar to those in the fifth embodiment.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application Nos. 2008-162317, filed Jun. 20, 2008, 2008-170687, filed Jun. 30, 2008, and 2009-064676, filed Mar. 17, 2009, which are hereby incorporated by reference herein in their entirety.

1. A light-emitting apparatus comprising a plurality of light-emitting devices which are connected in series and formed by alternately disposing electrodes and organic layers comprising a light-emitting material, wherein
the electrodes include one electrode and another electrode disposed at an anode end and a cathode end of the light-emitting devices, respectively, and an intermediate electrode disposed between two of the organic layers which serves as a cathode of the light-emitting device disposed on a side of the anode end and as an anode of the light-emitting device disposed on a side of the cathode end;
the intermediate electrode is connected to a drive circuit having two current output terminals connected in common;
the drive circuit receives data signals concerning two of the plurality of light-emitting devices for which the intermediate electrode serves as the anode and the cathode, respectively; and
the drive circuit outputs currents which are different in direction from each other from the two current output terminals in response to the received data signals.

2. The light-emitting apparatus according to claim 1, wherein:
the data signals comprise two data signals concerning respective luminances of the two light-emitting devices for which the intermediate electrode serves as the cathode and the anode, respectively; and
the current flowing in a direction toward the intermediate electrode and the current flowing in a direction from the intermediate electrode are generated based on the two data signals and output from the two current output terminals, respectively.

3. The light-emitting apparatus according to claim 1, wherein the data signals comprise:
signals concerning an absolute value and a sign of a difference between two currents which are determined based on respective luminances of the two light-emitting devices for which the intermediate electrode serves as the cathode and the anode.

4. The light-emitting apparatus according to claim 3, further comprising:
a circuit for calculating two current values corresponding to the respective luminances of the two light-emitting devices for which the intermediate electrode serves as the cathode and the anode;
a circuit for generating signals concerning the absolute value and the sign of the difference between the two calculated current values;
a circuit for generating a current corresponding to the signal concerning the absolute value; and
two switches which are each provided at the two current output terminals, and are opened and closed in response to the signal concerning the sign.

5. The light-emitting apparatus according to claim 1, wherein the one electrode and another electrode disposed at both ends thereof are connected to a fixed voltage source and a current source for generating a current in one direction, respectively.

6. The light-emitting apparatus according to claim 5, wherein:
the number of the plurality of light-emitting devices is at least three; and
each of the intermediate electrode is connected to the drive circuit.

7. The light-emitting apparatus according to claim 5, wherein a group of the drive circuits connected to the electrodes provided at both ends thereof and the drive circuit connected to the intermediate electrode comprises a current mirror circuit for outputting currents which are opposite in direction from each other and are equal in absolute value to each other.

8. The light-emitting apparatus according to claim 1, wherein:
the plurality of light-emitting devices comprise two light-emitting devices;
among the electrodes, a pair of the electrodes disposed at both ends thereof are short-circuited; and
the drive circuit alternately outputs the currents which are opposite in direction from each other from the two current output terminals.

9. The light-emitting apparatus according to claim 8, wherein:
the plurality of light-emitting devices include two pairs thereof; and
the drive circuits connected to the intermediate electrodes of the two pairs include a current source in common.

10. The light-emitting apparatus according to claim 8, wherein the currents which are different in direction from each other are alternately output from the two current output terminals.

11. The light-emitting apparatus according to claim 8, wherein:
the drive circuit is supplied with electric power from two power sources, the two power sources being fixed voltage sources which have different voltages; and
between a period in which one of the two power sources outputs a current and a period in which another thereof outputs a current, potentials of the two of the electrodes disposed at both ends of the light-emitting apparatus are switched between the voltages of the two power sources.

12. The light-emitting apparatus according to claim 1, further comprising:
pixels including the plurality of light-emitting devices and the drive circuit, the pixels being disposed in matrix in a row direction and in a column direction;
control lines connected in common to the drive circuit of the pixels disposed in the row direction; and
data lines connected in common to the drive circuit of the pixels disposed in the column direction, wherein:
the drive circuit comprises means for holding a plurality of the data signals supplied from the data lines in response to a control signal applied to the control lines;
the drive circuit outputs currents corresponding to the plurality of the data signals held during different periods; and
the pixels disposed in matrix are scanned once in one frame period in response to the control signal of the control lines.

13. The light-emitting apparatus according to claim 1, wherein the drive circuit comprises:
a capacitor for holding a signal corresponding to an output current; and
a circuit for outputting a current corresponding to a voltage held in the capacitor.

14. The light-emitting apparatus according to claim 1, wherein the drive circuit comprises:
a p-type transistor for outputting the current flowing in a direction toward the intermediate electrode; and
an n-type transistor for outputting the current flowing in a direction in which the current is drawn from the intermediate electrode.
